(19) United States
(12) Patent Application Publication
(10) Pub. No.: US 2013/0241358 A1
(43) Pub. Date: Sep. 19, 2013

(54) QUARTZ CRYSTAL DEVICE AND METHOD FOR FABRICATING THE SAME

(71) Applicant: NIHON DEMPA KOGYO CO., LTD., TOKYO (JP)

(72) Inventors: SHUICHI MIZUSAWA, SAITAMA (JP); TAKEHIRO TAKAHASHI, SAITAMA (JP)

(73) Assignee: NIHON DEMPA KOGYO CO., LTD., TOKYO (JP)

(21) Appl. No.: 13/794,802

(22) Filed: Mar. 12, 2013

(30) Foreign Application Priority Data
Mar. 14, 2012 (JP) 2012-057076

(51) Int. Cl. G03F 7/40; H03H 9/10

(52) U.S. Cl. CPC G03F 7/40; H03H 9/1014
USPC 310/348; 430/316

(57) ABSTRACT

A method for fabricating a quartz crystal device includes forming a corrosion-resistant film on a first surface and a second surface of the base wafer, forming and exposing a photoresist on the corrosion-resistant film, etching the corrosion-resistant film, and performing wet-etching on through holes. The through hole has, at a +X-axis side, a first inclined surface, a second inclined surface, and a first top formed at an intersection of the first and second inclined surface, and has, at a −X-axis side, a third inclined surface, a fourth inclined surface, and a second top connecting the third and fourth inclined surfaces. The exposing exposes the first and second surfaces such that a distance from a center in the X-axis direction to the first top becomes equal to a distance from the center to the second top in the base plate.

### CROSS REFERENCE TO RELATED APPLICATIONS

This application claims the priority benefit of Japan application serial no. 2012-057076, filed on Mar. 14, 2012. The entirety of the above-mentioned patent application is hereby incorporated by reference herein and made a part of this specification.

### TECHNICAL FIELD

This disclosure relates to a quartz crystal device that includes a quartz-crystal vibrating piece and a base plate, and to a method for fabricating the quartz crystal device. The quartz-crystal vibrating piece and the base plate are formed by wet-etching a quartz substrate.

### DESCRIPTION OF THE RELATED ART

It is preferred that a large amount of surface mount quartz crystal devices can be fabricated at a time. A quartz crystal device disclosed in Japanese Unexamined Patent Application Publication No. 2006-148758 (hereinafter referred to as Patent Literature 1) is fabricated such that a quartz-crystal wafer including a plurality of quartz-crystal vibrating pieces is sandwiched between a lid wafer and a base wafer with the same shape as the quartz-crystal wafer and made of a glass material. The method for fabricating the quartz crystal device disclosed in Patent Literature 1 forms through holes at the lid wafer and the base wafer, thus forming side portion wirings at four corners of the quartz crystal device (castellations). The side portion wiring electrically connects an excitation electrode and an external terminal of the quartz-crystal vibrating piece. The quartz crystal devices fabricated on a wafer scale are individually separated by dicing for completion.

However, since the quartz-crystal wafer differs in thermal expansion coefficient from the lid wafer or the base wafer, which are made of a glass material, the quartz crystal device is unusable in an environment where thermal fluctuation is large. On the other hand, in the case where the lid wafer or the base wafer is made of a quartz-crystal material, through holes formed on the lid wafer and the base wafer have varied wet-etching speeds depending on an axis direction due to anisotropy of the crystal, thus forming a different size of through hole in the axial direction. This does not allow forming castellations in positions with the same distance from the center of the quartz crystal device. The through holes are different in size depending on the axial direction. Accordingly, when the bonded wafer is diced into individual quartz crystal devices, side wiring formed on the castellation may be chipped off.

A need thus exists for a quartz crystal device and a method for fabricating the quartz crystal device which are not susceptible to the drawback mentioned above.

### SUMMARY

A method for fabricating a quartz crystal device according to a first aspect uses an AT-cut base wafer. The AT-cut base wafer includes a plurality of base plates in rectangular shapes. The base plate has at least a pair of through holes in an X-axis direction. The quartz crystal device includes a quartz-crystal vibrating piece and the base plate. The method includes forming a corrosion-resistant film on a first surface of the base wafer and a second surface at an opposite side of the first surface, exposing a photoresist on the first surface and the second surface in a position corresponding to the through hole after forming the photoresist on the corrosion-resistant film, etching the corrosion-resistant film corresponding to the through hole of the first surface and the second surface, and performing wet-etching on the first surface and the second surface to form the pair of through holes after the etching corrosion-resistant film. The through hole formed by the wet-etching connects the first surface to the second surface. The through hole has a cross section at a +X-axis side and a cross section at a −X-axis side. The cross section at the +X-axis side includes a first inclined surface, a second inclined surface, and a first top. The first inclined surface is formed toward a center side of the cross section from the first surface. The second inclined surface is formed toward the center side of the cross section from the second surface. The first top is formed at an intersection of the first inclined surface and the second inclined surface. The cross section at the −X-axis side includes a third inclined surface, a fourth inclined surface, and a second top. The third inclined surface is formed toward the center side of the cross section from the first surface. The fourth inclined surface is formed toward the center side of the cross section from the second surface. The second top connects the third inclined surface to the fourth inclined surface. The exposing exposes the first surface and the second surface in a position corresponding to the through hole such that a distance from a center in the X-axis direction of the base plate to the first top becomes equal to a distance from the center in the X-axis direction of the base plate to the second top.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a quartz crystal device 100;

FIG. 2 is a cross-sectional view taken along the line A-A of FIG. 1;

FIG. 3A is a plan view of a surface at the +Y′-axis side of the base plate 120;

FIG. 3B is a plan view of a surface at the −Y′-axis side of the base plate 120;

FIG. 4A is a plan view of the base plate 120 where an electrodes has not been formed;

FIG. 4B is a cross-sectional view taken along the line B-B of FIG. 4A;

FIG. 5 is a flowchart illustrating a method for fabricating the quartz crystal device 100;

FIG. 6A is a plan view of the surface at the +Y′-axis side of the base wafer W120;

FIG. 6B is a plan view of the surface at the −Y′-axis side of the base wafer W120;

FIGS. 7A to 7D illustrate a flowchart of a method for fabricating the base wafer W120;

FIGS. 8A to 8D illustrate a flowchart of the method for fabricating the base wafer W120;

FIG. 9 is a plan view of a surface at the +Y′-axis side of a lid wafer W110;

FIG. 10A is a partial cross-sectional view of the base wafer W120 where a quartz-crystal vibrating piece 130 has been placed;

FIG. 10B is a partial cross-sectional view of the quartz-crystal vibrating piece 130, the base wafer W120, and the lid wafer W110;

FIG. 11A is a cross-sectional view of a base plate 120a;

FIG. 11B is a cross-sectional view of a base plate 120b;

FIG. 12 is an exploded perspective view of a quartz crystal device 200a;

FIG. 13 is a cross-sectional view taken along the line E-E of FIG. 12;

FIG. 14A is a plan view of a surface at the +Y′-axis side of a quartz-crystal vibrating piece 230a;

FIG. 14B is a plan view of a surface at the −Y′-axis side of the quartz-crystal vibrating piece 230a;

FIG. 14C is a cross-sectional view of the quartz-crystal vibrating piece 230a;

FIG. 15A is a plan view of a surface at the +Y′-axis side of a base plate 220a;

FIG. 15B is a plan view of a surface at the −Y′-axis side of the base plate 220a;

FIG. 15C is a cross-sectional view of the base plate 220a;

FIG. 16 is a plan view of a quartz-crystal wafer W230;

FIG. 17A to 17D illustrate a flowchart of a method for fabricating the quartz-crystal wafer W230;

FIG. 18A to 18D illustrate a flowchart of the method for fabricating the quartz-crystal wafer W230;

FIG. 19A is a plan view of a surface at the +Y′-axis side of a base wafer W220;

FIG. 19B is a plan view of a surface at the −Y′-axis side of the base wafer W220;

FIG. 20A is a partial cross-sectional view of the base wafer W220 where the quartz-crystal wafer W230 is placed;

FIG. 20B is a partial cross-sectional view of the quartz-crystal wafer W230, the base wafer W220, and the lid wafer W110;

FIG. 21 is an exploded perspective view of a quartz crystal device 300;

FIG. 22A is a cross-sectional view taken along the line H-H of FIG. 21;

FIG. 22B is a plan view of a surface at the −Y′-axis side of the quartz crystal device 300;

FIG. 23A is a plan view of a surface at the +Y′-axis side of a base plate 320; and

FIG. 23B is a cross-sectional view of the base plate 320.

### DETAILED DESCRIPTION

The preferred embodiments of this disclosure will be described with reference to the attached drawings. It will be understood that the scope of the disclosure is not limited to the described embodiments, unless otherwise stated.

### Configuration of a Quartz Crystal Device 100 of a First Embodiment

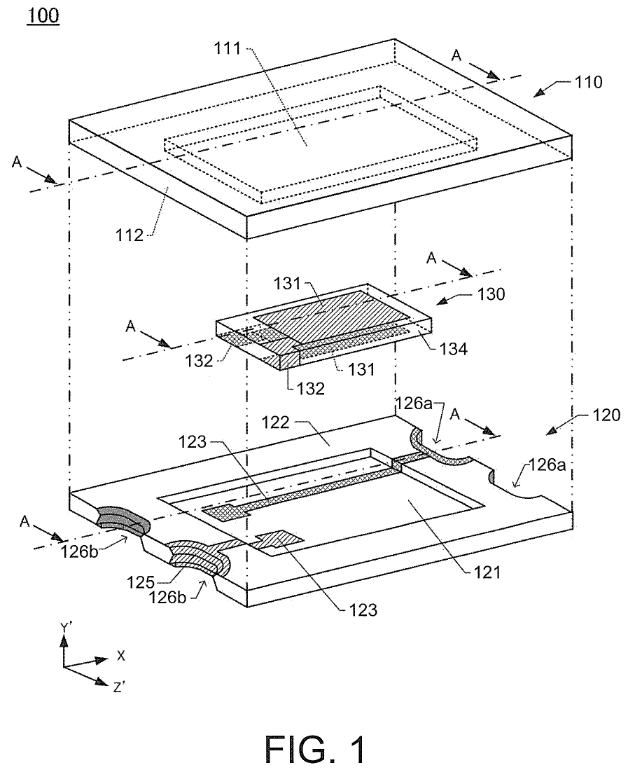

FIG. 1 is an exploded perspective view of a quartz crystal device 100. The quartz crystal device 100 includes a lid plate 110, a base plate 120, and a quartz-crystal vibrating piece 130. The quartz-crystal vibrating piece 130 and the base plate 120 employ, for example, an AT-cut crystal wafer. The AT-cut crystal wafer has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut crystal wafer are denoted as the Y′-axis and the Z′-axis. This disclosure defines, in the quartz crystal device 100, the long side direction of the quartz crystal device 100 as the X-axis direction, the height direction of the quartz crystal device 100 as the Y′-axis direction, and the direction perpendicular to the X and Y′-axis directions as the Z′-axis direction.

The quartz-crystal vibrating piece 130 includes a vibrator 134, an excitation electrode 131, and an extraction electrode 132. The vibrator 134 vibrates at a predetermined vibration frequency and has a rectangular shape. The excitation electrodes 131 are formed on surfaces at the +Y′-axis side and the −Y′-axis side of the vibrator 134. The extraction electrode 132 is extracted from each excitation electrode 131 to the −X-axis side. The extraction electrode 132 is extracted from the excitation electrode 131 that is formed on the surface at the +Y′-axis side of the vibrator 134. The extraction electrode 132 is extracted from the excitation electrode 131 to the −X-axis side, and is further extracted to the surface at the −Y′-axis side of the vibrator 134 via the side surface at the +Z′-axis side of the vibrator 134. The extraction electrode 132 is extracted from the excitation electrode 131 that is formed on the surface at the −Y′-axis side of the vibrator 134. The extraction electrode 132 is extracted from the excitation electrode 131 to the −X-axis side, and is formed up to the corner at the −X-axis side and the −Z′-axis side of the vibrator 134.

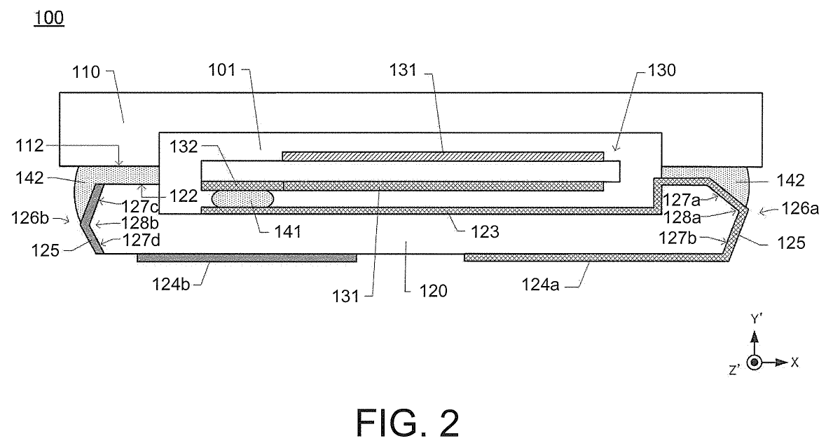

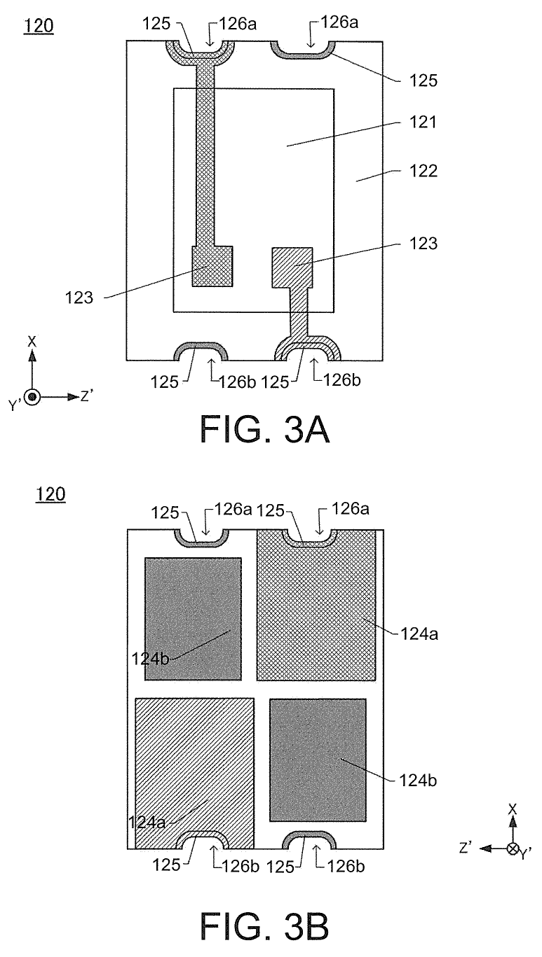

The base plate 120 employs a base material of the AT-cut crystal wafer with the surface where an electrode is formed. A bonding surface 122 is formed at the peripheral area of the surface at the +Y′-axis side of the base plate 120. The bonding surface 122 is to be bonded to the lid plate 110 via a sealing material 142 (see FIG. 2). The base plate 120 includes a depressed portion 121 at the center of the surface at the +Y′-axis side. The depressed portion 121 is depressed from the bonding surface 122 in the −Y′-axis direction. The depressed portion 121 includes a pair of connecting electrodes 123. Each connecting electrode 123 electrically connects to an extraction electrode 132 of the quartz-crystal vibrating piece 130 via a conductive adhesive 141 (see FIG. 2). The base plate 120 includes a mounting terminal on the surface at the −Y′-axis side. The mounting terminal mounts the quartz crystal device 100 to a printed circuit board or similar member. In the base plate 120, the mounting terminal includes a hot terminal 124a (see FIG. 2 and FIG. 3B) and a grounding terminal 124b (see FIG. 2 and FIG. 3B). The hot terminal 124a is a terminal that electrically connects to an external electrode and a similar member for applying a voltage to the quartz crystal device 100. At the +Z′-axis side and the −Z′-axis side of a side surface at the +X-axis side of the base plate 120, castellations 126a depressed toward the inside of the base plate 120 are formed. At the +Z′-axis side and the −Z′-axis side of a side surface at the −X-axis side of the base plate 120, castellations 126b depressed toward the inside of the base plate 120 are formed. The castellations 126a and the castellations 126b have side surfaces where respective side surface electrodes 125 are formed. The hot terminal 124a electrically connects to the connecting electrode 123 via the side surface electrode 125.

The lid plate 110 includes a depressed portion 111 on the surface at the −Y′-axis side. The depressed portion 111 is depressed in the +Y′-axis direction. A bonding surface 112 is formed to surround the depressed portion 111. The bonding surface 112 is to be bonded to the bonding surface 122 of the base plate 120 via the sealing material 142 (see FIG. 2).

FIG. 2 is a cross-sectional view taken along the line A-A of FIG. 1. A sealed cavity 101 is formed in the quartz crystal device 100 by bonding the bonding surface 122 of the base plate 120 and the bonding surface 112 of the lid plate 110 together via the sealing material 142. The cavity 101 houses the quartz-crystal vibrating piece 130. The extraction electrode 132 electrically connects to the connecting electrode 123 of the base plate 120 via the conductive adhesive 141. The hot terminal 124a electrically connects to the connecting electrode 123 via the side surface electrodes 125. Accordingly, the excitation electrode 131 electrically connects to the hot terminal 124a.

The castellation 126a formed at the +X-axis side of the base plate 120 has a side surface formed of a first inclined surface 127a and a second inclined surface 127b. The first inclined surface 127a connects to the surface at the +Y′-axis side of the base plate 120. The second inclined surface 127b connects to the surface at the −Y′-axis side of the base plate 120. The first inclined surface 127a and the second inclined surface 127b intersect with each other at a first top 128a. The castellation 126b formed at the −X-axis side of the base plate 120 has a side surface formed of a third inclined surface 127c and a fourth inclined surface 127d. The third inclined surface 127c connects to the surface at the +Y′-axis side of the base plate 120. The fourth inclined surface 127d connects to the surface at −Y′-axis side of the base plate 120. The third inclined surface 127c and the fourth inclined surface 127d intersect with each other at a second top 128b. The first top 128a is formed at the +X-axis side of the base plate 120 compared with the first inclined surface 127a and the second inclined surface 127b. The second top 128b is formed at the −X-axis side of the base plate 120 compared with the third inclined surface 127c and the fourth inclined surface 127d. In the base plate 120 of the quartz crystal device 100, as illustrated in FIG. 2, the sealing material 142 is also formed on the first inclined surface 127a and the third inclined surface 127c. Accordingly, the base plate 120 is bonded to the bonding surface 112 of the lid plate 110 at the first inclined surface 127a, the third inclined surface 127c, and the bonding surface 122.

FIG. 3A is a plan view of the surface at the +Y′-axis side of the base plate 120. The base plate 120 includes the depressed portion 121 at the center of the surface at the +Y′-axis side. The bonding surface 122 is formed to surround the depressed portion 121. Castellations 126a are formed at the +Z′-axis side and the −Z′-axis side on the side surfaces at the +X-axis side of the base plate 120. Castellations 126b are formed at the +Z′-axis side and the −Z′-axis side on the side surfaces at the −X-axis side. The depressed portion 121 includes the pair of connecting electrodes 123. The castellation 126a and the castellation 126b each include the side surface electrodes 125. The pair of connecting electrodes 123 electrically connect to the side surface electrodes 125 of the castellation 126a formed at the +X-axis side and the −Z′-axis side and the castellation 126b formed at the −X-axis side and the +Z′-axis side.

FIG. 3B is a plan view of the surface at the −Y′-axis side of the base plate 120. The surface at the −Y′-axis side of the base plate 120 includes, as the mounting terminals, the pair of hot terminals 124a and the pair of grounding terminals 124b. One hot terminal 124a is formed at the +X-axis side and the −Z′-axis side while the other hot terminal 124a is formed at the −X-axis side and the +Z′-axis side on the surface at the −Y′-axis side of the base plate 120. The hot terminals 124a electrically connect to the respective side surface electrodes 125. One grounding terminal 124b is formed at the +X-axis side and the +Z′-axis side while the other grounding terminal 124b is formed at the −X-axis side and the −Z′-axis side of the base plate 120. While in the base plate 120 illustrated in FIG. 3B, the grounding terminals 124b does not electrically connect to the side surface electrodes 125, the grounding terminals 124b may electrically connect to the side surface electrodes 125.

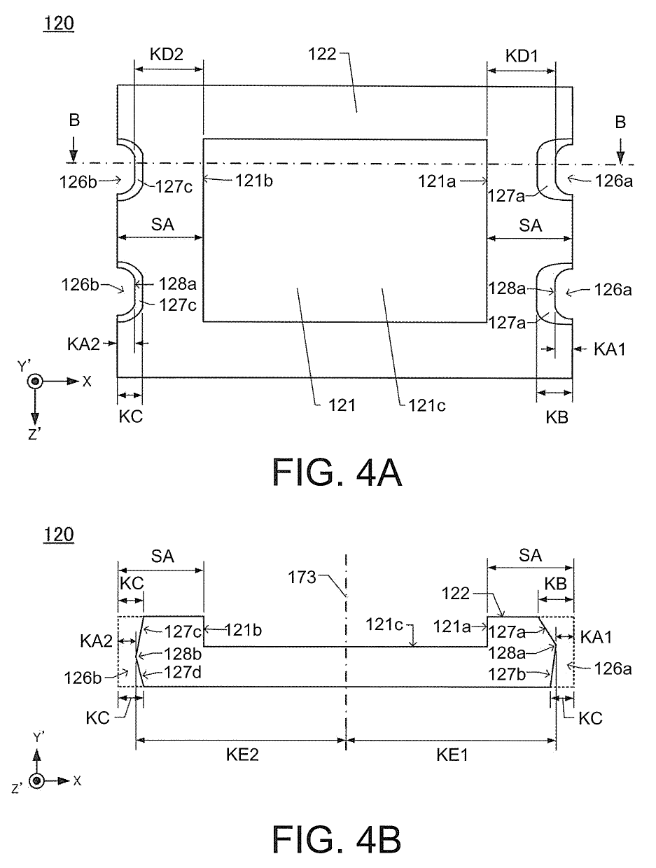

FIG. 4A is a plan view of the base plate 120 where an electrode has not been formed. The depressed portion 121 of the base plate 120 includes a sidewall and a bottom surface 121c. In the base plate 120, the depressed portion 121 has respective widths SA of the bonding surface 122 in the X-axis direction at the +X-axis side and the −X-axis side. Furthermore, the base plate 120 has a width KB of the castellation 126a in the X-axis direction on the surface at the +Y′-axis side while the base plate 120 has a width KA1 of the castellation 126a in the X-axis direction on the first top 128a. The base plate 120 has a width KC of the castellation 126b in the X-axis direction on the surface at the +Y′-axis side while the base plate 120 has a width KA2 of the castellation 126b in the X-axis direction on the second top 128b. A sidewall 121a at the +X-axis side of the depressed portion 121 and the first top 128a form a width KD1 while a sidewall 121b at the −X-axis side of the depressed portion 121 and the second top 128b form a width KD2. The width KD1 and the width KD2 are respectively a width at the −X-axis side of the castellation 126a and a width at the +X-axis side of the castellation 126b in the bonded area over which the sealing material 142 is actually to be applied. In the base plate 120, the width KA1 is equal to the width KA2 while the width KD1 is equal to the width KD2.

FIG. 4B is a cross-sectional view taken along the line B-B of FIG. 4A. The castellation 126a and the castellation 126b each have a width KC in the X-axis direction on the surface at the −Y′-axis side. In the castellation 126a and the castellation 126b, the first top 128a and the second top 128b each have the narrowest width in the X-axis direction. The base plate 120 has a distance KE1 between the center 173 and the first top 128a in the X-axis direction while the base plate 120 has a distance KE2 between the center 173 and the second top 128b. The distance KE1 is equal to the distance KE2.

### Method for Fabricating the Quartz Crystal Device 100

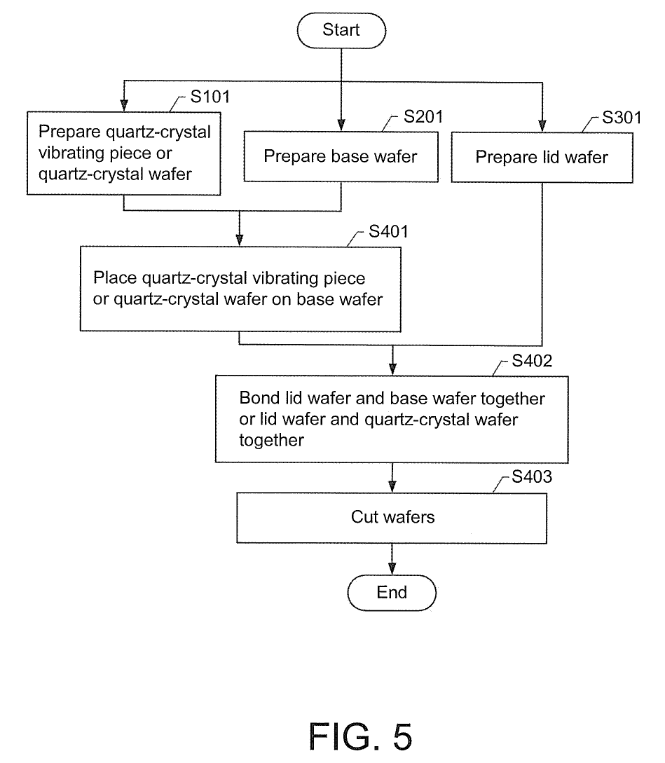

FIG. 5 is a flowchart illustrating a method for fabricating the quartz crystal device 100. Hereinafter, a description will be given of the method for fabricating the quartz crystal device 100 following the flowchart of FIG. 5.

In step S101, a plurality of quartz-crystal vibrating pieces 130 are prepared. Step S101 is a process for preparing a quartz-crystal vibrating piece. In step S101, first, outlines of the plurality of quartz-crystal vibrating piece 130 are formed on a quartz-crystal wafer, which is made of a quartz-crystal material, by etching or similar method. Further, the excitation electrode 131 and the extraction electrode 132 are formed on each quartz-crystal vibrating piece 130 by a method such as sputtering or vacuum evaporation. The plurality of quartz-crystal vibrating pieces 130 are prepared by folding and removing the quartz-crystal vibrating piece 130 from the quartz-crystal wafer.

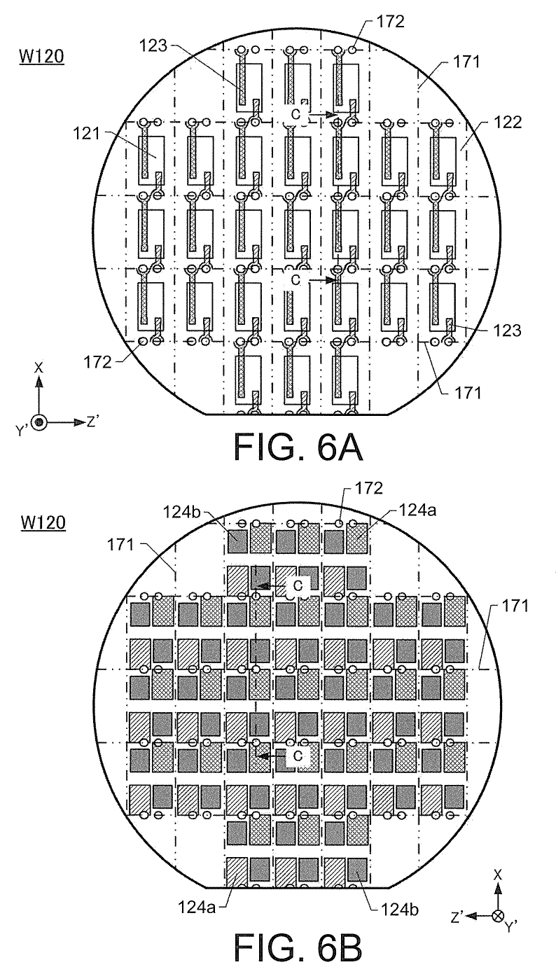

In step S201, the base wafer W120 is prepared. Step S201 is a process for preparing a base wafer. A plurality of base plates 120 are formed on the base wafer W120. The base wafer W120 employs a base material of the AT-cut quartz-crystal material. On the base wafer W120, the depressed portion 121 and a through hole 172 (see FIG. 6A and FIG. 6B) are formed by etching. The through hole 172 becomes the castellation 126a or the castellation 126b after the base wafer W120 is cut. On the base wafer W120, the connecting electrode 123, the side surface electrodes 125, the hot terminal 124a, and the grounding terminal 124b are formed.

FIG. 6A is a plan view of the surface at the +Y′-axis side of the base wafer W120. The base wafer W120 includes a plurality of base plates 120. Each base plate 120 is aligned in the X-axis direction and the Z′-axis direction. In FIG. 6A, a scribe line 171 is illustrated at a boundary between the base plates 120 adjacent one another. The scribe line 171 is a line that indicates a position at which the wafer is cut in step S403, which will be described below. On the scribe line 171 extending in the X-axis direction, the through hole 172 is formed. The through hole 172 passes through the base wafer W120 in the Y′-axis direction. After the wafer is cut in step S403 described below, the through hole 172 becomes the castellation 126a and the castellation 126b. On the surface at the +Y′-axis side of each base plate 120, the depressed portion 121 and the connecting electrode 123 are formed.

FIG. 6B is a plan view of the surface at the −Y′-axis side of the base wafer W120. The base wafer W120 has the surface at the −Y′-axis side where the hot terminal 124a and the grounding terminal 124b are formed. The hot terminal 124a electrically connects to the connecting electrode 123 via the side surface electrodes 125 formed at the through hole 172. In the base wafer W120, the side surface electrode 125 formed at one through hole 172 electrically connects to one hot terminal 124a only.

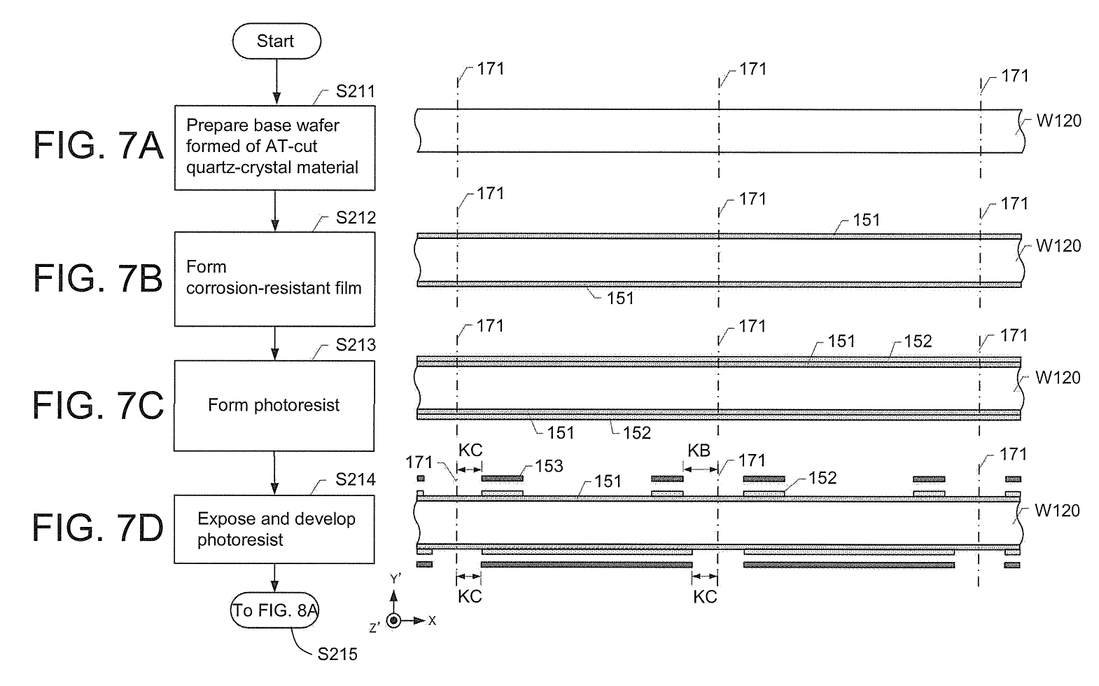

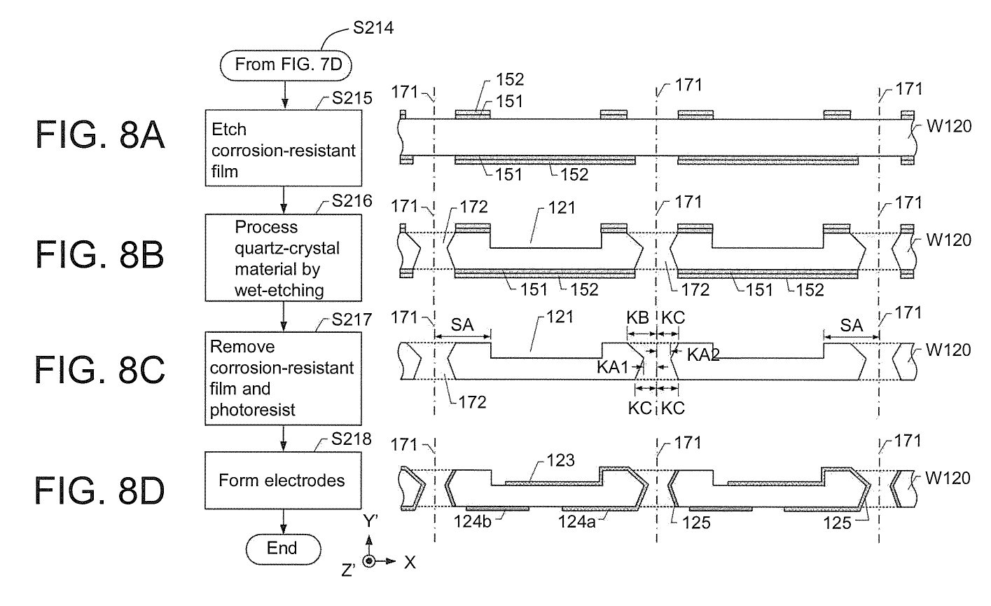

FIGS. 7A to 7D and FIGS. 8A to 8D illustrate a flowchart of a method for fabricating the base wafer W120. Hereinafter, by referring to FIGS. 7A to 7D and FIGS. 8A to 8D, a detailed description will be given of step S201 in FIG. 5, which is a process for preparing the base wafer W120.

In step S211 of FIGS. 7A to 7D, a base wafer formed of an AT-cut quartz-crystal material is prepared. FIG. 7A is a partial cross-sectional view of the base wafer W120 formed of an AT-cut quartz-crystal material. FIG. 7A and views in FIGS. 7A to 7D and FIGS. 8A to 8D described below are cross-sectional views of cross sections corresponding to the cross section taken along the line C-C of FIG. 6A and FIG. 6B. Each cross-sectional view illustrates the scribe line 171. An area surrounded by the scribe lines 171 forms one base plate 120. The base wafer W120 prepared in step S211 is formed in a planar shape.

In step S212, a corrosion-resistant film is formed. FIG. 7B is a partial cross-sectional view of the base wafer W120 where a corrosion-resistant film 151 has been formed. The corrosion-resistant film 151 is formed on the surfaces at the +Y′-axis side and the −Y′-axis side of the base wafer W120. The corrosion-resistant film 151 is formed, for example, by forming a chromium (Cr) layer (not shown) on the surfaces at the +Y′-axis side and the −Y′-axis side of the base wafer W120 and forming a gold (Au) layer (not shown) on a surface of the chromium layer. Step S212 is a process for forming the corrosion-resistant film.

In step S213, a photoresist is formed. FIG. 7C is a partial cross-sectional view of the base wafer W120 where a photoresist 152 has been formed. The photoresist 152 is formed on the surface of the corrosion-resistant film 151, which is formed in step S212.

In step S214, the photoresist is exposed and developed. FIG. 7D is a partial cross-sectional view of the base wafer W120 where the photoresist has been exposed and developed. The base wafer W120 is exposed through a mask 153, and developed to remove the photoresist 152. The photoresist 152 to be removed in step S214 is on an area where the through hole 172 and the depressed portion 121 on the surface at the +Y′-axis side of the base wafer W120 are formed, and on an area where the through hole 172 on the surface at the −Y′-axis side of the base wafer W120 is formed. The photoresist 152 to be removed for forming the through hole 172 has the width KB from the scribe line 171 at the +X-axis side on the surface at +Y′-axis side of each base plate 120. The photoresist 152 has the width KC from the scribe line 171 at the −X-axis side on the surface at the +Y′-axis side, and at the +X-axis side and the −X-axis side on the surface at the −Y′-axis side of each base plate 120. The width KB is about 10 to 30% wider than the width KC. Step S213 and Step S214 are exposure processes.

In step S215 of FIGS. 8A to 8D, the corrosion-resistant film is etched. FIG. 8A is a partial cross-sectional view of the base wafer W120 where the corrosion-resistant film 151 has been etched. In step S215, the corrosion-resistant film 151 with an exposed surface where the photoresist 152 has been removed in step S214 is removed by etching. This exposes the quartz-crystal material in the area where the through hole 172 and the depressed portion 121 are to be formed on the base wafer W120. Step S215 is a process for etching the corrosion-resistant film.

In step S216, the quartz-crystal material is processed by wet-etching. FIG. 8B is a partial cross-sectional view of the base wafer W120 where the quartz-crystal material has been etched. In step S216, the quartz-crystal material is processed by wet-etching to form the through hole 172 and the depressed portion 121 in the base wafer W120. The base wafer W120 employs the base material of the AT-cut quartz-crystal material. Thus, anisotropy of the crystal causes the through hole 172 with a side surface near the center portion that is narrow toward the inside of the through hole 172. Step S216 is a wet-etching process.

In step S217, the corrosion-resistant film and the photoresist are removed. FIG. 8C is a partial cross-sectional view of the base wafer W120 where the corrosion-resistant film 151 and the photoresist 152 have been removed. At the through hole 172, a width in the −X-axis direction and a width in the +X-axis direction from the scribe line 171 to the side surface of the base plate 120 are respectively the width KA1 and the width KA2. The width KA1 is equal to the width KA2.

In step S218, electrodes are formed on the base wafer W120. FIG. 8D is a partial cross-sectional view of the base wafer W120 where the electrodes have been formed. In step S218, the chromium layer is formed on the base wafer W120. The gold layer is formed on the surface of the chromium layer to form the connecting electrode 123, the hot terminal 124a, the grounding terminal 124b, and the side surface electrodes 125 on the base wafer W120.

Returning to FIG. 5, in step S301, the lid wafer W110 is prepared. On the lid wafer W110, a plurality of lid plates 110 are formed. On the surface at the −Y′-axis side of each lid plate 110, the depressed portion 111 is formed.

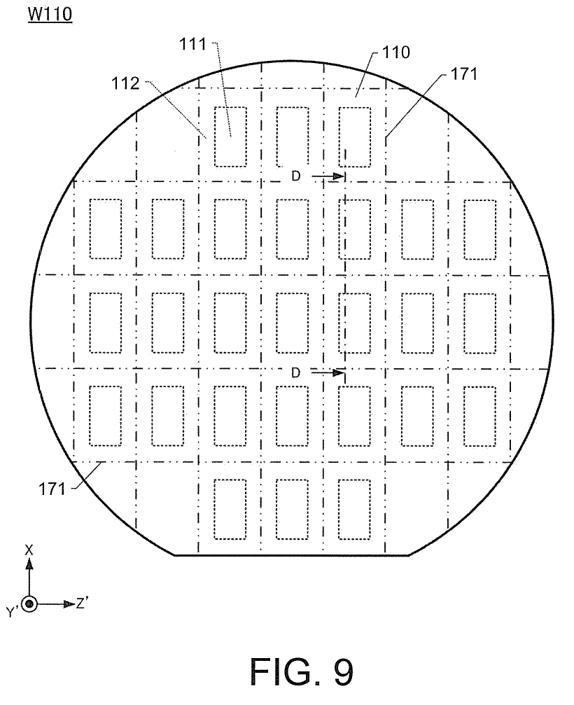

FIG. 9 is a plan view of the surface at the +Y′-axis side of a lid wafer W110. On the lid wafer W110, a plurality of lid plates 110 are formed. On the surface at the −Y′-axis side of each lid plate 110, the depressed portion 111 and the bonding surface 112 are formed. In FIG. 9, a two-dot chain line is drawn between the lid plates 110 adjacent one another. This two-dot chain lines become the scribe lines 171.

In step S401, the quartz-crystal vibrating piece 130 is placed on the base wafer W120. The quartz-crystal vibrating piece 130 is placed on each depressed portion 121 on the base wafer W120 with the conductive adhesive 141.

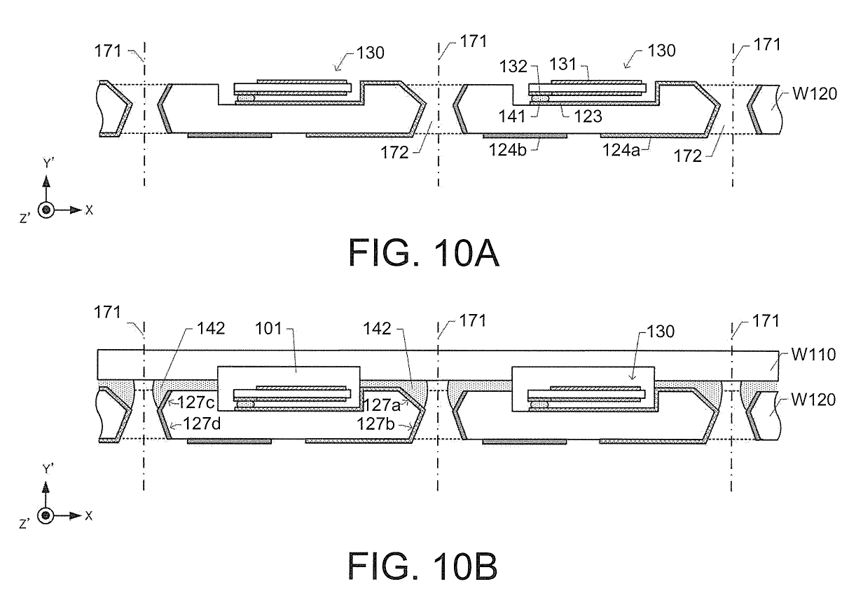

FIG. 10A is a partial cross-sectional view of the base wafer W120 where a quartz-crystal vibrating piece 130 has been placed. FIG. 10A illustrates a cross-sectional view including a cross section taken along the line C-C of FIG. 6A and FIG. 6B. The extraction electrode 132 and the connecting electrode 123 of the quartz-crystal vibrating piece 130 are electrically connected together via the conductive adhesive 141. Thus, the quartz-crystal vibrating piece 130 is placed on the depressed portion 121 of the base wafer W120. This electrically connects the excitation electrode 131 and the hot terminal 124a, which is formed on the surface at the −Y′-axis side of the base wafer W120.

In step S402, the base wafer W120 and the lid wafer W110 are bonded together. The base wafer W120 and the lid wafer W110 are bonded such that the bonding surface 122, the first inclined surface 127a, and the third inclined surface 127c of the base wafer W120 face the bonding surface 112 of the lid wafer W110 via the sealing material 142.

FIG. 10B is a partial cross-sectional view of the quartz-crystal vibrating piece 130, the base wafer W120, and the lid wafer W110. FIG. 10B illustrates a cross-sectional view including a cross section taken along the line C-C of FIG. 6A and FIG. 6B and a cross section taken along the line D-D of FIG. 9. The base wafer W120 and the lid wafer W110 are bonded such that the bonding surface 122, the first inclined surface 127a, and the third inclined surface 127c face the bonding surface 112 via the sealing material 142. The lid wafer W110 and the base wafer W120 are bonded together via the sealing material 142. Thus, the sealed cavity 101 is formed. In the cavity 101, the quartz-crystal vibrating piece 130 is placed.

In step S403, the base wafer W120 and the lid wafer W110 are cut. The base wafer W120 and the lid wafer W110 are cut (diced) with a dicing blade (not shown) along the scribe line 171 to form individual quartz crystal devices 100. Step S403 is a dicing process. As illustrated in FIG. 10B, the scribe line 171 at the through hole 172 has a distance of the width KA2 from the side surface electrodes 125 at the +X-axis side of the scribe line 171. Additionally, the scribe line 171 has a distance of the width KA1 from the side surface electrodes 125 at the −X-axis side of the scribe line 171. The quartz crystal device 100 is formed to have the width KA1 equal to the width KA2. Accordingly, the scribe line 171 is the most distant from the side surface electrodes 125. This prevents the side surface electrodes 125 from being chipped off by a dicing blade.

Since the AT-cut quartz-crystal material is anisotropic in wet-etching. The castellations formed on the base plate changes in shape and dimensions at the +X-axis side and the −X-axis side of the base plate. For example, in FIG. 4B, the width KA1 and the width KA2 may be different. In such a case, the side surface electrodes formed on the side surface of the castellation may have been chipped off in the dicing process. In the case where the base plate has different bonded areas of the sealing material at the +X-axis side and at the −X-axis side, variation in bonding strength of the sealing material at the +X-axis side and at the −X-axis side of the base plate easily break the seal of the cavity at a weak bonding strength side.

The quartz crystal device 100 is formed to have the width KA1 equal to the width KA2, thus preventing the side surface electrodes 125 from being chipped off in the dicing process. The width KD1 is formed to be equal to the width KD2. Thus, the base plate 120 has the same widths at the +X-axis side and the −X-axis side in the bonded area. This provides the same bonding strengths of the sealing material 142 at the +X-axis side and the −X-axis side of the cavity 101. This prevents breaking the seal of the cavity 101.

### Modification of the Base Plate 120

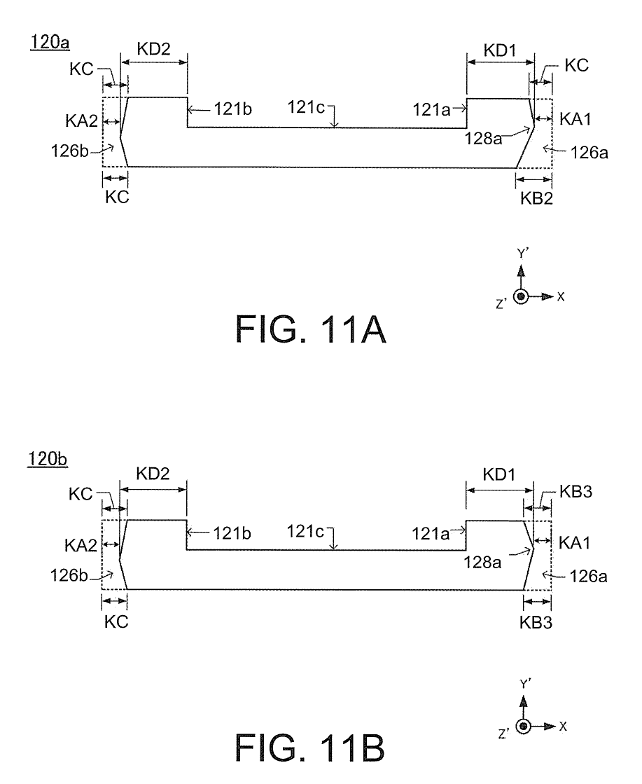

FIG. 11A is a cross-sectional view of the base plate 120a. The base plate 120a is a modification of the base plate 120. FIG. 11A illustrates a cross-sectional view of the base plate 120a corresponding to the cross section of the base plate 120 in FIG. 4B. The base plate 120a has a width KB2 in the X-axis direction on the surface at the −Y′-axis side of the castellation 126a at the +X-axis side while the base plate 120a has the width KC in the X-axis direction on the surface at the +Y′-axis side. In the base plate 120a, a size of the width KB2 is adjusted to form the width KA1 equal to the width KA2. In the base plate 120a, similarly to the base plate 120, the width KD1 is equal to the width KD2.

FIG. 11B is a cross-sectional view of a base plate 120b. The base plate 120b is a modification of the base plate 120. FIG. 11B illustrates a cross-sectional view of the base plate 120b corresponding to the cross section of the base plate 120 in FIG. 4B. The base plate 120b has a width KB3 in the X-axis direction on the surfaces at the +Y′-axis side and the −Y′-axis side of the castellation 126a at the +X-axis side. In the base plate 120b, a size of the width KB3 is adjusted to form the width KA1 equal to the width KA2. In the base plate 120b, similarly to the base plate 120, the width KD1 is equal to the width KD2.

### Second Embodiment

The quartz-crystal vibrating piece may employ a quartz-crystal vibrating piece where a framing body surrounds the peripheral area of the vibrator. Hereinafter, a description will be given of a quartz crystal device 200a that employs the quartz-crystal vibrating piece with the framing body. The embodiment will now be described wherein like reference numerals designate corresponding or identical elements throughout the embodiments.

### Configuration of the Quartz Crystal Device 200a

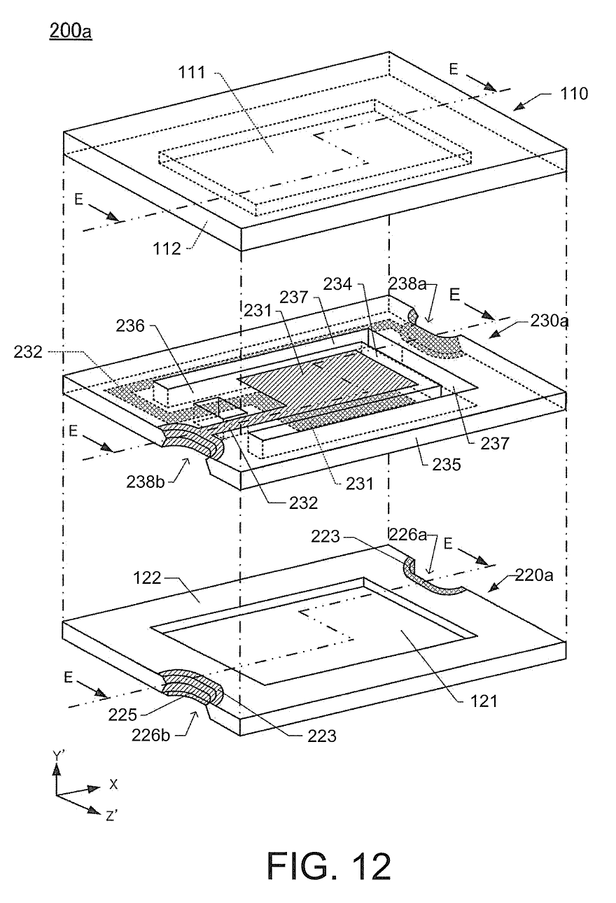

FIG. 12 is an exploded perspective view of the quartz crystal device 200a. The quartz crystal device 200a includes the lid plate 110, a base plate 220a, and a quartz-crystal vibrating piece 230a. The quartz crystal device 200a employs, similarly to the first Embodiment, an AT-cut quartz-crystal vibrating piece as the quartz-crystal vibrating piece 230a.

The quartz-crystal vibrating piece 230a vibrates at a predetermined vibration frequency and includes a vibrator 234, a framing body 235, and connecting portions 236. The vibrator 234 is formed in a rectangular shape. The framing body 235 is formed to surround the peripheral area of the vibrator 234. The connecting portions 236 connect the vibrator 234 and the framing body 235 together. Between the vibrator 234 and the framing body 235, through grooves 237 are formed. The through grooves 237 pass through the quartz-crystal vibrating piece 230a in the Y′-axis direction. The vibrator 234 and the framing body 235 do not directly contact each other. At the +X-axis side and the −Z′-axis side of the framing body 235, a castellation 238a is formed. At the −X-axis side and the +Z′-axis side of the framing body 235, a castellation 238b is formed. The vibrator 234 and the framing body 235 are connected together at the +Z′-axis side and the −Z′-axis side at the −X-axis side of the vibrator 234 by the connecting portions 236. On the surface at the +Y′-axis side and the surface at the −Y′-axis side of the vibrator 234, excitation electrodes 231 are formed. From each of the excitation electrodes 231, an extraction electrode 232 is extracted to the framing body 235. The extraction electrode 232, which is extracted from the excitation electrode 231 on the surface at the +Y′-axis side of the vibrator 234, is extracted via the connecting portion 236 at the +Z′-axis side and the castellation 238b at the −X-axis side. The extraction electrode 232 is extracted to the −X-axis side and the +Z′-axis side of the surface at the −Y′-axis side of the framing body 235. The extraction electrode 232, which is extracted from the excitation electrode 231 on the surface at the −Y′-axis side of the vibrator 234, is extracted via the connecting portion 236 at the −Z′-axis side. The extraction electrode 232 is extracted to the −X-axis side of the framing body 235, and additionally extracted to the castellation 238a at the +X-axis side of the framing body 235 and the peripheral area of the castellation 238a.

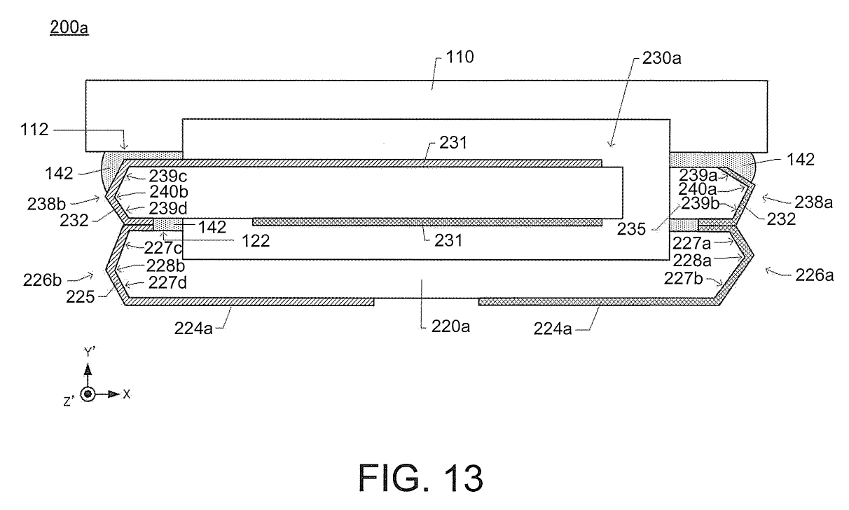

In the base plate 220a, the bonding surface 122 is formed in the peripheral area of the surface at the +Y′-axis side of the base plate 220a. The bonding surface 122 is to be bonded on the surface at the −Y′-axis side of the framing body 235 via the sealing material 142 (see FIG. 13). In the center of the surface at the +Y′-axis side of the base plate 220a, the depressed portion 121 depressed from the bonding surface 122 in the −Y′-axis direction is formed. At the −Z′-axis side of a side surface at the +X-axis side of the base plate 220a, a castellation 226a depressed toward inside of the base plate 220a is formed. At the +Z′-axis side of the side surface at the −X-axis side of the base plate 220a, a castellation 226b depressed toward inside of the base plate 220a is formed. The castellation 226a and the castellation 226b each have a side surface where a side surface electrode 225 is formed. The castellation 226a and the castellation 226b of the bonding surface 122 each have a peripheral area where a connecting electrode 223 is formed. The connecting electrodes 223 electrically connect to the extraction electrode 232 and the side surface electrodes 225 of the quartz-crystal vibrating piece 230a. Furthermore, the base plate 220a has the surface at the −Y′-axis side where a pair of mounting terminals 224a (see FIG. 13) is formed. Each of the mounting terminals 224a electrically connects to the corresponding side surface electrode 225 formed at the castellation 226a or the castellation 226b.

FIG. 13 is a cross-sectional view taken along the line E-E of FIG. 12. In the quartz crystal device 200a, the bonding surface 112 of the lid plate 110 is bonded to the surface at the +Y′-axis side of the framing body 235 via the sealing material 142 while the bonding surface 122 of the base plate 220a is bonded to the surface at the −Y′-axis side of the framing body 235 via the sealing material 142. In the bonding of the quartz-crystal vibrating piece 230a and the base plate 220a, the castellation 238a of the quartz-crystal vibrating piece 230a and the castellation 226a of the base plate 220a are stacked in the Y′-axis direction while the castellation 238b of the quartz-crystal vibrating piece 230a and the castellation 226b of the base plate 220a are stacked in the Y′-axis direction. When the quartz-crystal vibrating piece 230a and the base plate 220a are bonded together, the extraction electrode 232 and the connecting electrode 223 are electrically bonded together. This electrically connects the excitation electrode 231 to the mounting terminal 224a.

The side surface of the castellation 238a formed at the +X-axis side of the quartz-crystal vibrating piece 230a is formed of a first inclined surface 239a and a second inclined surface 239b. The first inclined surface 239a connects to the surface at the +Y′-axis side of the framing body 235 in the quartz-crystal vibrating piece 230a. The second inclined surface 239b connects to the surface at the −Y′-axis side of the framing body 235 in the quartz-crystal vibrating piece 230a. The first inclined surface 239a and the second inclined surface 239b intersect with each other at a first top 240a. The side surface of the castellation 238b formed at the −X-axis side of the quartz-crystal vibrating piece 230a is formed of a third inclined surface 239c and a fourth inclined surface 239d. The third inclined surface 239c connects to the surface at the +Y′-axis side of the framing body 235 in the quartz-crystal vibrating piece 230a. The fourth inclined surface 239d connects to the surface at the −Y′-axis side of the framing body 235 in the quartz-crystal vibrating piece 230a. The third inclined surface 239c and the fourth inclined surface 239d intersect with each other at a second top 240b. The first top 240a is formed at the +X-axis side of the quartz-crystal vibrating piece 230a compared with the first inclined surface 239a and the second inclined surface 239b. The second top 240b is formed at the −X-axis side of the quartz-crystal vibrating piece 230a compared with the third inclined surface 239c and the fourth inclined surface 239d.

The quartz-crystal vibrating piece 230a includes the +Y′-axis side of the framing body 235 where the sealing material 142 is formed in an area that includes the first inclined surface 239a and the third inclined surface 239c. On the surface at the −Y′-axis side of the framing body 235, the extraction electrode 232 connects to the connecting electrode 223. Accordingly, the sealing material 142 is not formed on the extraction electrode 232 that directly connects to the connecting electrode 223.

The side surface of the castellation 226a formed at the +X-axis side of the base plate 220a is formed of a first inclined surface 227a and a second inclined surface 227b. The first inclined surface 227a connects to the bonding surface 112 of the base plate 220a. The second inclined surface 227b connects to the surface at the −Y′-axis side of the base plate 220a. The first inclined surface 227a and the second inclined surface 227b intersect with each other at a first top 228a. The side surface of the castellation 226b formed at the −X-axis side of the base plate 220a is formed of a third inclined surface 227c and a fourth inclined surface 227d. The third inclined surface 227c connects to the bonding surface 112 of the base plate 220a. The fourth inclined surface 227d connects to the surface at the −Y′-axis side of the base plate 220a. The third inclined surface 227c and the fourth inclined surface 227d intersect with each other at a second top 228b. The first top 228a is formed at the +X-axis side of the base plate 220a compared with the first inclined surface 227a and the second inclined surface 227b. The second top 228b is formed at the −X-axis side of the base plate 220a compared with the third inclined surface 227c and the fourth inclined surface 227d.

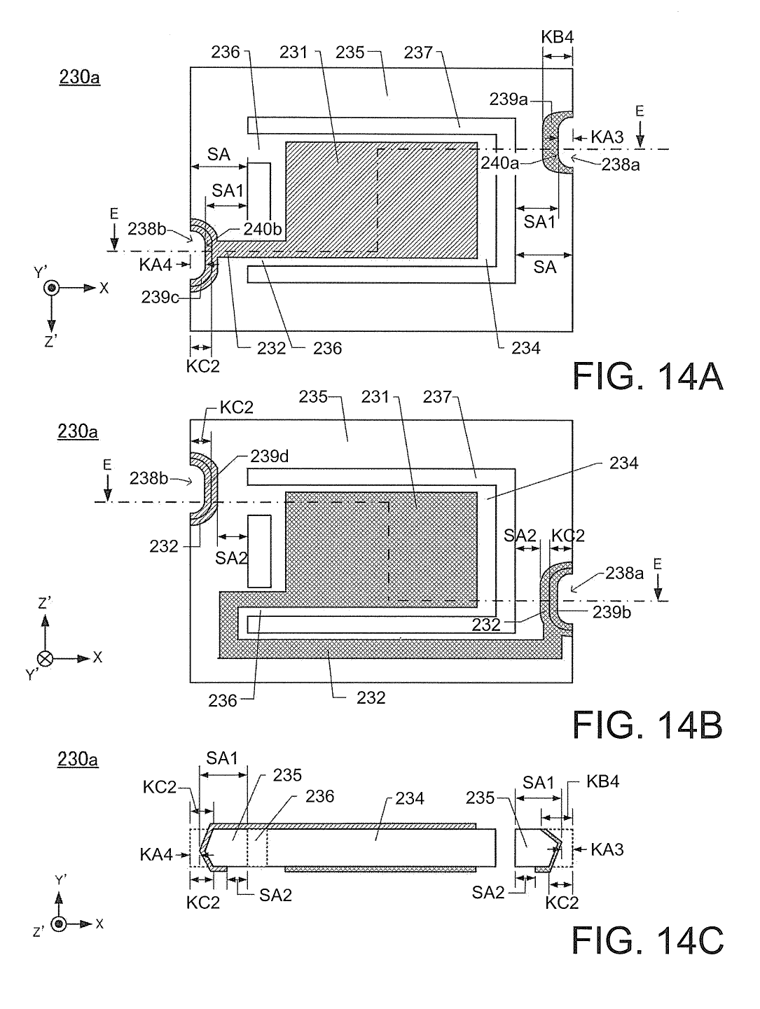

FIG. 14A is a plan view of the surface at the +Y′-axis side of the quartz-crystal vibrating piece 230a. From the excitation electrode 231 formed on the surface at the +Y′-axis side of the vibrator 234, the extraction electrode 232 passes through the connecting portion 236, and is extracted to the castellation 238b formed at the −X-axis side of the framing body 235. The castellation 238b formed at the −X-axis side of the framing body 235 has a width KC2 in the X-axis direction on the surface at the +Y′-axis side. The castellation 238b has a width KA4 in the X-axis direction of the second top 240b. The framing body 235 at the −X-axis side of the vibrator 234 has a width SA in the X-axis direction. The bonded area at the +X-axis side of the castellation 238b has a width SA1.

The castellation 238a formed at the +X-axis side of the framing body 235 has a width KB4 in the X-axis direction on the surface at the +Y′-axis side. The castellation 238a has a width KA3 in the X-axis direction of the first top 240a. The framing body 235 has the width SA in the X-axis direction. The castellation 238a has the width SA1 of the bonded area at the −X-axis side.

FIG. 14B is a plan view of the surface at the −Y′-axis side of the quartz-crystal vibrating piece 230a. From the excitation electrode 231 formed at the −Y′-axis side of the vibrator 234, the extraction electrode 232 passes through the connecting portion 236 at the −Z′-axis side, is extracted to the framing body 235, and is further extracted to the peripheral area of the castellation 238a formed at the +X-axis side of the framing body 235.

The castellation 238a formed at the +X-axis side of the framing body 235 has the width KC2 in the X-axis direction on the surface at the −Y′-axis side. A portion excluding the extraction electrode 232 formed in the peripheral area of the castellation 238a has a width SA2 in the X-axis direction of the framing body 235. The castellation 238b formed at the −X-axis side of the framing body 235 has the width KC2 in the X-axis direction on the surface at the −Y′-axis side. A portion excluding the extraction electrode 232 formed in the peripheral area of the castellation 238b has the width SA2 in the X-axis direction of the framing body 235. These areas with the width SA2 are bonded areas where the framing body 235 is bonded to the base plate 220a via the sealing material 142.

FIG. 14C is a cross-sectional view of the quartz-crystal vibrating piece 230a. FIG. 14C illustrates a cross-sectional view taken along the line E-E of FIG. 14A and FIG. 14B. On the surface at the +Y′-axis side of the framing body 235 in the quartz-crystal vibrating piece 230a, the sealing material 142 is formed in the area with the width SA1. On the surface at the −Y′-axis side of the framing body 235, the sealing material 142 is formed in the area with the width SA2. The areas where the sealing material 142 is formed are uniformly formed at the +X-axis side and the −X-axis side of the quartz-crystal vibrating piece 230a. In the quartz-crystal vibrating piece 230a, the width KA3 is equal to the width KA4.

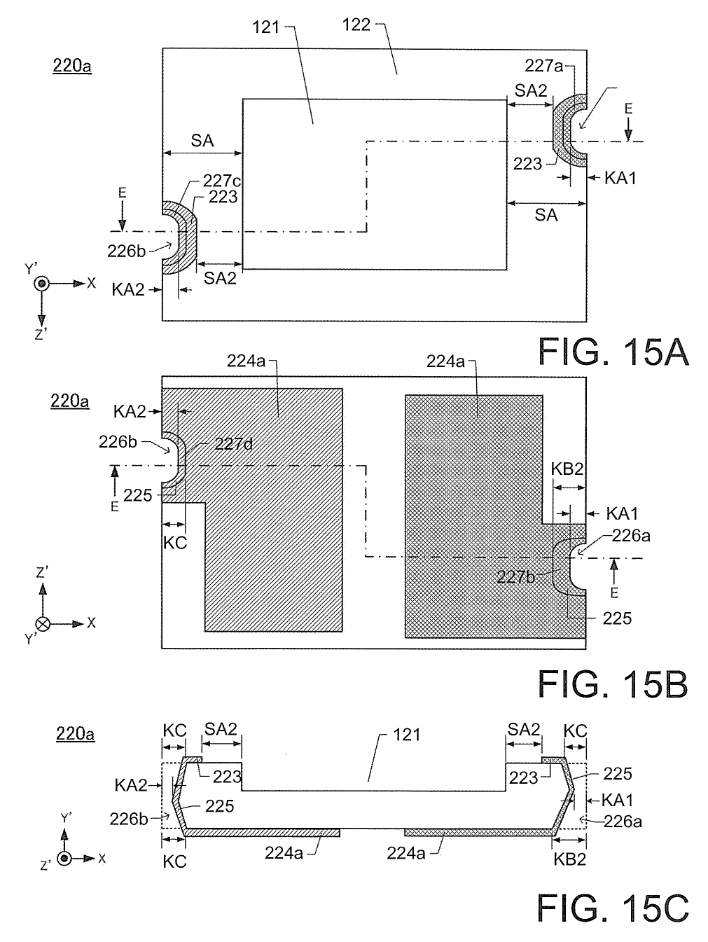

FIG. 15A is a plan view of the surface at the +Y′-axis side of a base plate 220a. The base plate 220a has the width SA in the X-axis direction at each of the +X-axis side and the −X-axis side of the depressed portion 121 on the bonding surface 122. Portions excluding the respective connecting electrodes 223 at the −X-axis side of the castellation 226a and the +X-axis side of the castellation 226b have the width SA2 in the X-axis direction on the bonding surface 122. These areas with the width SA2 are bonded areas to be bonded to the surface at the −Y′-axis side of the framing body 235 in the quartz-crystal vibrating piece 230a via the sealing material 142. The first top 228a of the castellation 226a has the width KA1 in the X-axis direction while the second top 228b of the castellation 226b has the width KA2 in the X-axis direction. In the base plate 220a, the width KA1 is equal to the width KA2.

FIG. 15B is a plan view of the surface at the −Y′-axis side of the base plate 220a. On the surface at the −Y′-axis side of the base plate 220a, a pair of mounting terminals 224a are formed. Each mounting terminal 224a electrically connects to the corresponding side surface electrodes 225 where the castellation 226a or the castellation 226b is formed. The surface at the −Y′-axis side of the castellation 226a has the width KB2 in the X-axis direction while the surface at the −Y′-axis side of the castellation 226b has the width KC in the X-axis direction.

FIG. 15C is a cross-sectional view of the base plate 220a. In the base plate 220a, the surface at the −Y′-axis side of the castellation 226a has the width KB2 that is about 10% to 30% larger than the width KC in the X-axis direction. This forms the width KA1 equal to the width KA2.

### Method for Fabricating the Quartz Crystal Device 200a

The quartz crystal device 200a can be fabricated according to the flowchart illustrated in FIG. 5. Hereinafter, a description will be given of the method for fabricating the quartz crystal device 200a by referring to the flowchart of FIG. 5.

In step S101, a quartz-crystal wafer is prepared. In step S101, the quartz-crystal wafer W230 is prepared. The quartz-crystal wafer W230 includes a plurality of quartz-crystal vibrating pieces 230a and a plurality of quartz-crystal vibrating pieces 230b.

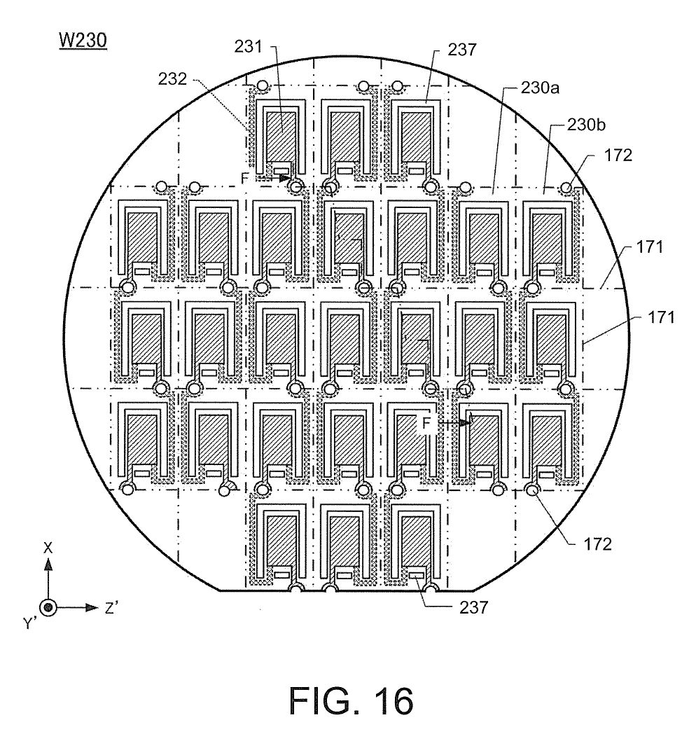

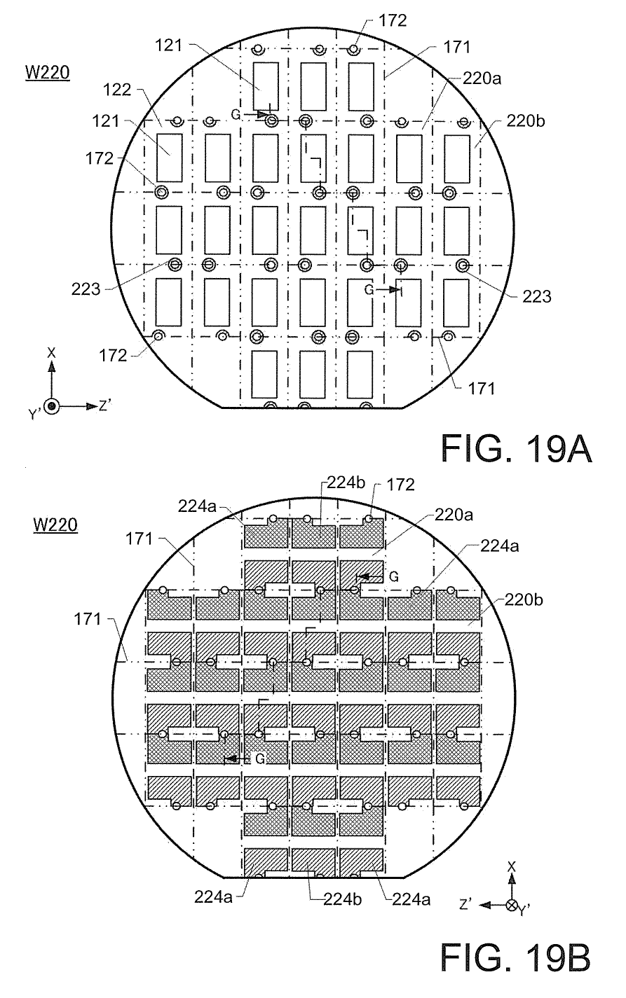

FIG. 16 is a plan view of the quartz-crystal wafer W230. The quartz-crystal wafer W230 includes the plurality of quartz-crystal vibrating pieces 230a and the plurality of quartz-crystal vibrating pieces 230b. The quartz-crystal vibrating piece 230b is formed to be mirror symmetric of the quartz-crystal vibrating piece 230a. The quartz-crystal vibrating piece 230b has dimensions of, for example, the framing body 235 and the castellations 238a and 238b, which are similar to the dimensions of the quartz-crystal vibrating piece 230a. In the quartz-crystal wafer W230, the quartz-crystal vibrating piece 230a and the quartz-crystal vibrating piece 230b are alternately formed in the X-axis direction and the Z′-axis direction. In the fabrication of the quartz crystal device 200a, the quartz crystal device 200b is also fabricated simultaneously with the quartz crystal device 200a. The quartz crystal device 200b is formed of the lid plate 110, the quartz-crystal vibrating piece 230b, and the base plate 220b (see FIG. 19A and FIG. 19B).

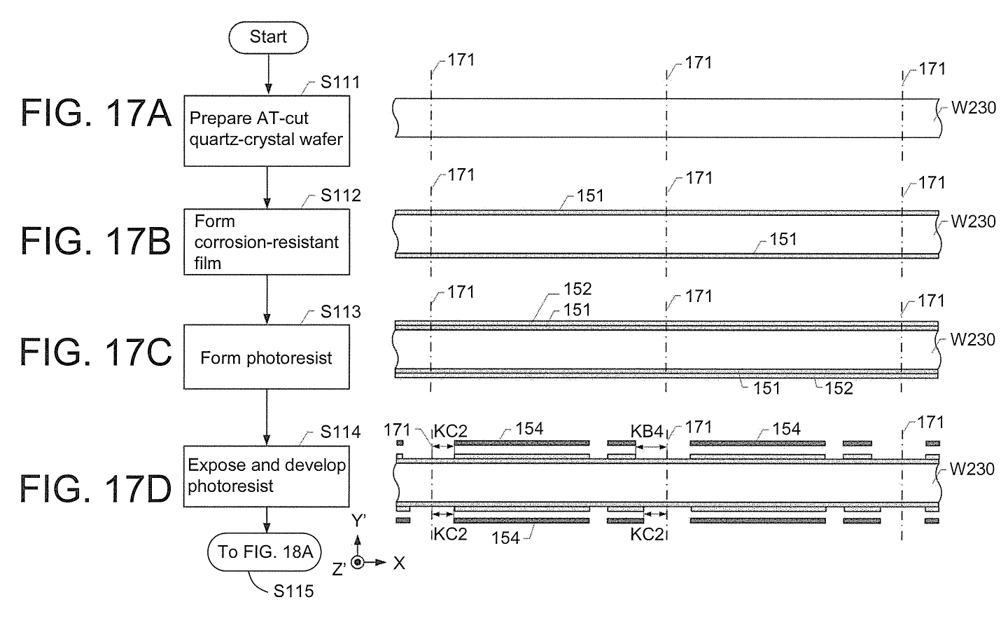

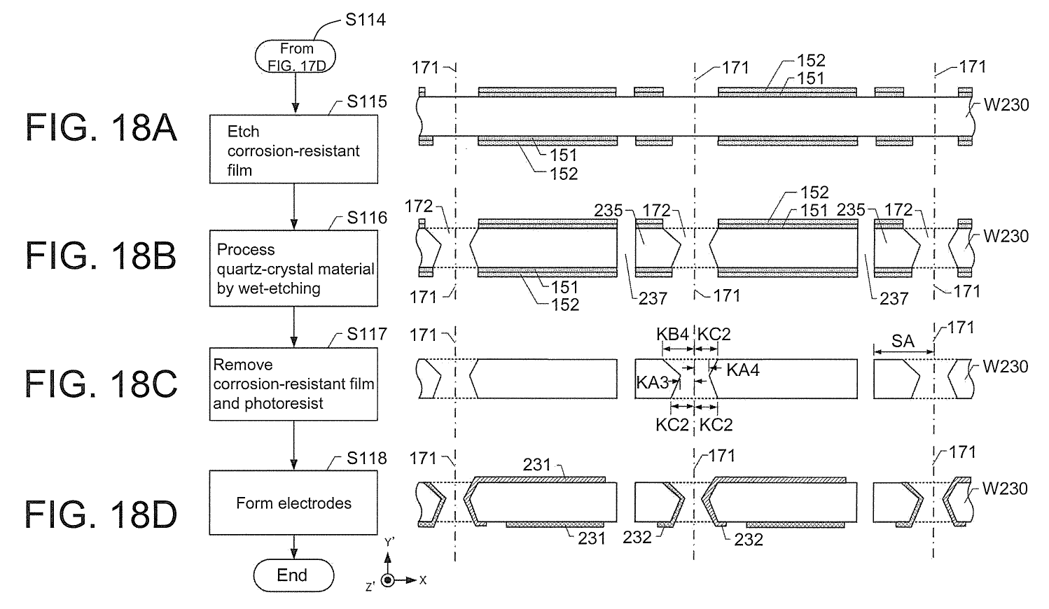

FIGS. 17A to 17D and FIGS. 18A to 18D illustrate a flowchart of a method for fabricating the quartz-crystal wafer W230. Hereinafter, by referring to FIGS. 17A to 17D and FIGS. 18A to 18D, a detailed description will be given of step S101 in FIG. 5 that is a process for preparing a quartz-crystal wafer.

In step S111 of FIGS. 17A to 17D, an AT-cut quartz-crystal wafer is prepared. FIG. 17A is a partial cross-sectional view of the AT-cut quartz-crystal wafer W230. FIG. 17A and views in FIGS. 17A to 17D and FIGS. 18A to 18D described below are cross-sectional views of cross sections corresponding to the cross section taken along the line F-F of FIG. 16. Each cross-sectional view illustrates the scribe lines 171. An area surrounded by the scribe lines 171 forms one quartz-crystal vibrating piece 230a. The quartz-crystal wafer W230 prepared in step S111 is formed in a planar shape.

In step S112, a corrosion-resistant film is formed. FIG. 17B is partial cross-sectional view of the quartz-crystal wafer W230 where the corrosion-resistant film 151 has been formed. The corrosion-resistant film 151 is formed on the surfaces at the +Y′-axis side and the −Y′-axis side of the quartz-crystal wafer W230. The corrosion-resistant film 151 is formed, for example, by forming a chromium (Cr) layer (not shown) on the surfaces at the +Y′-axis side and the −Y′-axis side of the quartz-crystal wafer W230 and forming a gold (Au) layer (not shown) on a surface of the chromium layer. Step S112 is a process for forming the corrosion-resistant film.

In step S113, a photoresist is formed. FIG. 17C is a partial cross-sectional view of the quartz-crystal wafer W230 where the photoresist 152 has been formed. The photoresist 152 is formed on the surface of the corrosion-resistant film 151, which is formed in step S112.

In step S114, the photoresist is exposed and developed. FIG. 17D is a partial cross-sectional view of the quartz-crystal wafer W230 where the photoresist 152 has been exposed and developed. The quartz-crystal wafer W230 is exposed through a mask 154, and developed to remove the photoresist 152. The photoresist 152 to be removed in step S114 is on an area where the through hole 172 and the through groove 237 on the surface at the +Y′-axis side of the quartz-crystal wafer W230 are formed, and on an area where the through hole 172 and the through groove 237 on the surface at the −Y′-axis side of the quartz-crystal wafer W230 are formed. The photoresist 152 to be removed for forming the through hole 172 has the width KB4 from the scribe line 171 at the +X-axis side on the surface at the +Y′-axis side of each quartz-crystal vibrating piece 230a and each quartz-crystal vibrating piece 230b. The photoresist 152 has the width KC2 from the scribe line 171 at the −X-axis side on the surface of the +Y′-axis side, and at the +X-axis side and the −X-axis side on the surface at the −Y′-axis side of each quartz-crystal vibrating piece 230a and each quartz-crystal vibrating piece 230b. Step S113 and step S114 are exposure processes.

In step S115 of FIGS. 18A to 18D, the corrosion-resistant film 151 is etched. FIG. 18A is a partial cross-sectional view of the quartz-crystal wafer W230 where the corrosion-resistant film 151 has been etched. In step S115, the corrosion-resistant film 151 with an exposed surface which is removed in step S114 is removed by etching. This exposes the quartz-crystal material in the area where the through hole 172 and the through groove 237 are formed on the quartz-crystal wafer W230. Step S115 is a process for etching the corrosion-resistant film.

In step S116, the quartz-crystal material is processed by wet-etching. FIG. 18B is a partial cross-sectional view of the quartz-crystal wafer W230 where the quartz-crystal material has been processed by wet-etching. In step S116, the quartz-crystal material is processed by wet-etching to form the through hole 172 and the through groove 237 in the quartz-crystal wafer W230. The quartz-crystal wafer W230 employs the AT-cut quartz-crystal material. Thus, anisotropy of the crystal causes the through hole 172 with a side surface near the center portion that is narrow toward the inside of the through hole 172. Step S116 is a wet-etching process.

In step S117, the corrosion-resistant film 151 and the photoresist 152 are removed. FIG. 18C is a partial cross-sectional view of the quartz-crystal wafer W230 where the corrosion-resistant film 151 and the photoresist 152 have been removed. As illustrated in FIG. 18C, at the through hole 172, a width in the −X-axis direction and a width in the +X-axis direction from the scribe line 171 to the side surface of the base plate 220a are respectively the width KA3 and the width KA4. The width KA3 is equal to the width KA4.

In step S118, electrodes are formed on the quartz-crystal wafer W230. FIG. 18D is a partial cross-sectional view of the quartz-crystal wafer W230 where the electrodes have been formed. In step S118, the chromium layer is formed on the quartz-crystal wafer W230, and the gold layer is formed on the surface of the chromium layer. This forms the excitation electrode 231 and the extraction electrode 232 on the quartz-crystal wafer W230.

Returning to FIG. 5, in step S201, the base wafer is prepared. In step S201, the base wafer W220 that includes a plurality of base plates 220a and a plurality of base plates 220b are prepared.

FIG. 19A is a plan view of the surface at the +Y′-axis side of the base wafer W220. On the base wafer W220, the plurality of base plates 220a and the plurality of base plates 220b are formed. The base plate 220b is formed to be mirror symmetric of the base plate 220a. In the base wafer W220, the base plate 220a and the base plate 220b are alternately formed in the X-axis direction and the Z′-axis direction. The peripheral area of the through hole 172 of the bonding surface 122 has the connecting electrode 223.

FIG. 19B is a plan view of the surface at the −Y′-axis side of the base wafer W220. The base plate 220a has a pair of mounting terminals 224a while the base plate 220b has a pair of mounting terminals 224b. In the base wafer W220, one through hole 172 electrically connects to the mounting terminal 224a and the mounting terminal 224b.

Returning to FIG. 5, in step S301, the lid wafer W110 is prepared. In step S301, the lid wafer W110, which includes the plurality of lid plates 110, is prepared. In step S401, the quartz-crystal wafer W230 is placed on the base wafer W220. In step S401, the quartz-crystal wafer W230 is stacked on the base wafer W220 to place the quartz-crystal wafer W230 on the base wafer W220.

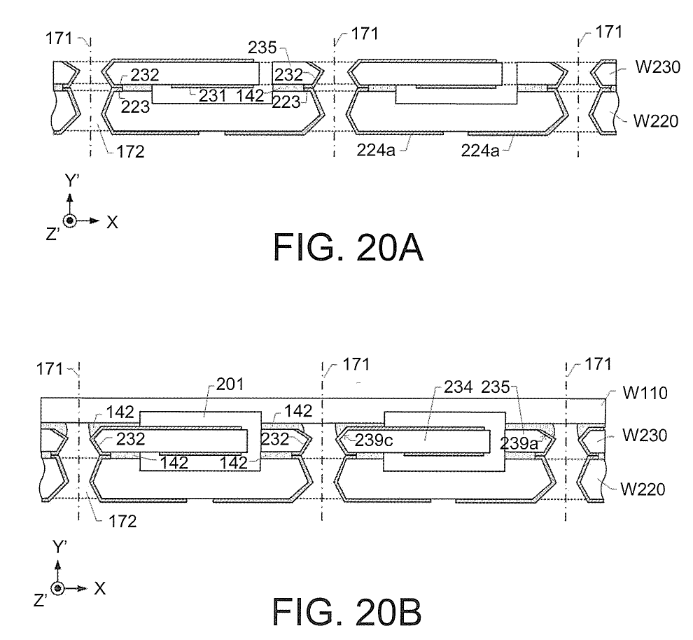

FIG. 20A is a partial cross-sectional view of the base wafer W220 where the quartz-crystal wafer W230 has been placed. FIG. 20A illustrates a cross-sectional view including a cross section taken along the line F-F of FIG. 16 and a cross section taken along the line G-G of FIG. 19A and FIG. 19B. The extraction electrode 232 and the connecting electrode 223 of the quartz-crystal wafer W230 are electrically connected together. The quartz-crystal wafer W230 and the base wafer W220 are bonded together by the sealing material 142. This electrically connects the excitation electrode 231 to the mounting terminal 224a on the surface at the −Y′-axis side of the base wafer W220.

In step S402, the quartz-crystal wafer W230 and the lid wafer W110 are bonded together. The quartz-crystal wafer W230 and the lid wafer W110 are bonded such that the sealing material 142 is applied over the surface at +Y′-axis side of the framing body on the quartz-crystal wafer W230 or the bonding surface 112 of the lid wafer W110, and then the framing body of the quartz-crystal wafer W230 faces the bonding surface 112 of the lid wafer W110 via the sealing material 142.

FIG. 20B is a partial cross-sectional view of the quartz-crystal wafer W230, the base wafer W220, and the lid wafer W110. FIG. 20B illustrates a cross-sectional view including a cross section taken along the line F-F of FIG. 16 and a cross section taken along the line G-G of FIG. 19A and FIG. 19B. The quartz-crystal wafer W230 and the lid wafer W110 are bonded together via the sealing material 142 on the surface at the +Y′-axis side of the framing body 235 and on the bonding surface 122. The sealing material 142 in the quartz-crystal wafer W230 is applied not only over the bonding surface 122 but also over the first inclined surface 239a and the third inclined surface 239c. The lid wafer W110 and the'quartz-crystal wafer W230 are bonded together via the sealing material 142 to form the sealed cavity 201. The vibrator 234 is placed in the cavity 201.

In step S403, the quartz-crystal wafer W230, the base wafer W220, and the lid wafer W110 are cut. The quartz-crystal wafer W230, the base wafer W220, and the lid wafer W110 are cut (diced) along the scribe lines 171 to form individual quartz crystal devices 200a and individual quartz crystal devices 200b. Step S403 is a dicing process.

The quartz crystal device 200a is formed to have a uniform width of the bonded areas in the X-axis direction at the +X-axis side and the −X-axis side of the cavity 201. This prevents breaking the seal of the cavity 201. The width KA1 is formed to be equal to the width KA2 while the width KA3 is formed to be equal to the width KA4. This prevents the side surface electrodes 225 and the extraction electrode 232 from being chipped off in the dicing process.

### Third Embodiment

The quartz-crystal vibrating piece may employ a quartz-crystal vibrating piece where a framing body surrounds the peripheral area of the vibrator and the framing body does not include the castellation. Hereinafter, a description will be given of a quartz crystal device 300 that employs the quartz-crystal vibrating piece including the framing body without the castellation. The embodiment will now be described wherein like reference numerals designate corresponding or identical elements throughout the first Embodiment.

### Configuration of the Quartz Crystal Device 300

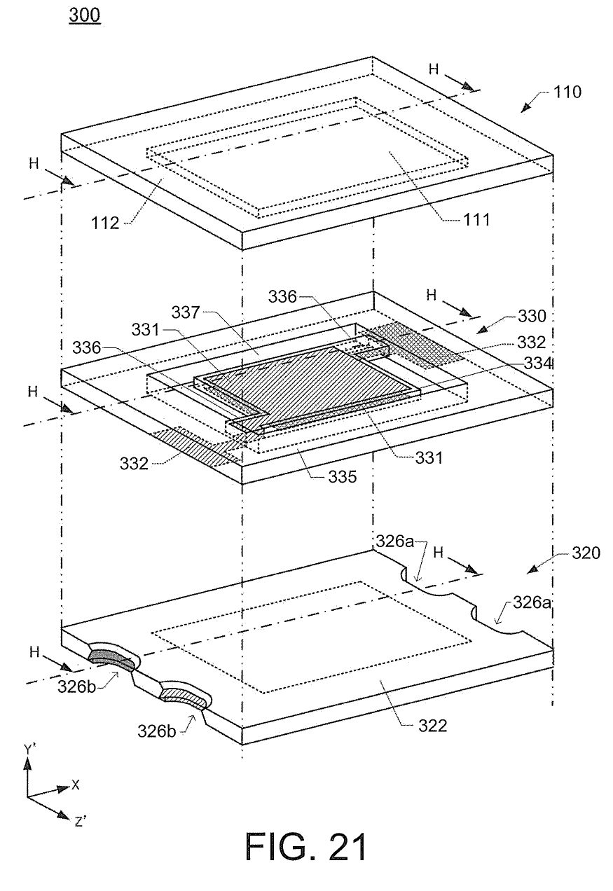

FIG. 21 is an exploded perspective view of the quartz crystal device 300. The quartz crystal device 300 includes the lid plate 110, a base plate 320, and a quartz-crystal vibrating piece 330. The quartz crystal device 300 employs, similarly to the first Embodiment, an AT-cut quartz-crystal vibrating piece as the quartz-crystal vibrating piece 330.

The quartz-crystal vibrating piece 330 vibrates at a predetermined vibration frequency and includes a vibrator 334, a framing body 335, and connecting portions 336. The vibrator 334 is formed in a rectangular shape. The framing body 335 surrounds the peripheral area of the vibrator 334. The connecting portion 336 connects the vibrator 334 and the framing body 335 together. Between the vibrator 334 and the framing body 335, through grooves 337 are formed. The through grooves 337 pass through the quartz-crystal vibrating piece 330 in the Y′-axis direction. The vibrator 334 and the framing body 335 do not directly contact each other. The vibrator 334 and the framing body 335 are connected together at the +Z′-axis side on the side surface at the −X-axis side of the vibrator 334 and at the −Z′-axis side on the side surface at the +X-axis side of the vibrator 334. In the quartz-crystal vibrating piece 330, thicknesses in the Y′-axis direction of the vibrator 334 and the connecting portion 336 are formed thinner than a thickness in the Y′-axis direction of the framing body 335. The surfaces at the +Y′-axis side and the surface at the −Y′-axis side of the vibrator 334 each have an excitation electrode 331. From each of the excitation electrodes 331, an extraction electrode 332 is extracted to the framing body 335. The extraction electrode 332, which is extracted from the excitation electrode 331 on the surface at the +Y′-axis side of the vibrator 334, is extracted via the connecting portion 336 at the +Z′-axis side. The extraction electrode 332 is extracted to the −X-axis side and the +Z′-axis side on the surface at the −Y′-axis side of the framing body 335. The extraction electrode 332, which is extracted from the excitation electrode 331 on the surface at the −Y′-axis side of the vibrator 334, is extracted via the connecting portion 336 at the −Z′-axis side. The extraction electrode 332 is extracted to the +X-axis side and the −Z′-axis side of the framing body 335.

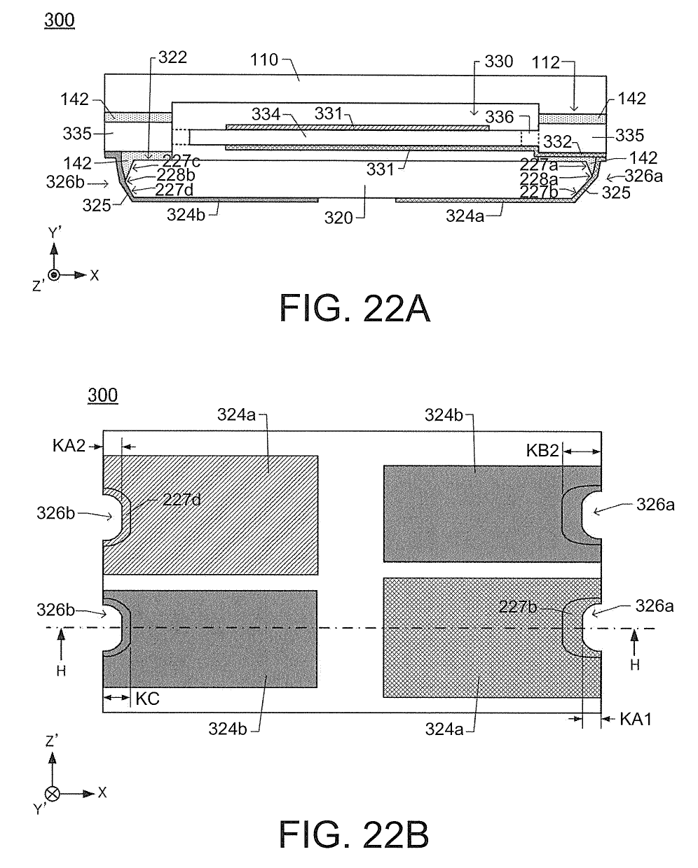

In the base plate 320, the surface at the +Y′-axis side does not have the depressed portion and is formed in a planar shape. In the quartz crystal device 300, a thickness of the vibrator 334 in the quartz-crystal vibrating piece 330 is formed thinner than a thickness of the framing body 335 (see FIG. 22A). Although the base plate 320 does not have the depressed portion, the vibrator 334 does not contact the base plate 320. In the base plate 320, the peripheral area of the surface at the +Y′-axis side has a bonding surface 322 to be bonded to the surface at the −Y′-axis side of the framing body 335 via the sealing material 142 (see FIG. 22A). The surface at the −Y′-axis side of the base plate 320 includes mounting terminals for mounting the quartz crystal device 300 on a printed circuit board or similar. In the base plate 320, the mounting terminals include hot terminals 324a, which electrically connects to an external electrode and a similar member, and grounding terminals 324b (see FIG. 22B). At the +Z′-axis side and the −Z′-axis side on the side surface at the +X-axis side, castellations 326a are formed. At the +Z′-axis side and the −Z′-axis side on the side surface at the −X-axis side, castellations 326b are formed. The hot terminal 324a electrically connects to the extraction electrode 332 of the quartz-crystal vibrating piece 330 via the castellation 326a or the castellation 326b.

FIG. 22A is a cross-sectional view taken along the line H-H of FIG. 21. The castellation 326a of the base plate 320 is formed in the same shape as the shape of the castellation 226a illustrated in FIG. 13, and includes the first inclined surface 227a, the second inclined surface 227b, and the first top 228a. The castellation 326b of the base plate 320 is formed in the same shape as the shape of the castellation 226b illustrated in FIG. 13, and includes the third inclined surface 227c, the fourth inclined surface 227d, and the second top 228b. In the quartz crystal device 300, the bonding surface 112 of the lid plate 110 and the surface at the +Y′-axis side of the framing body 335 are bonded together via the sealing material 142. The bonding surface 322, the first inclined surface 227a, and the third inclined surface 227c of the base plate 320 are bonded to the surface at the −Y′-axis side of the framing body 335 via the sealing material 142. The hot terminal 324a electrically connects to the extraction electrode 332 via the side surfaces of the castellation 326a or 326b and the sealing material 142. This electrically connects the excitation electrode 331 to the hot terminal 324a.

FIG. 22B is a plan view of a surface at the −Y′-axis side of the quartz crystal device 300. The surface at the −Y′-axis side of the base plate 320 that is the surface at the −Y′-axis side of the quartz crystal device 300 includes a pair of hot terminals 324a and a pair of grounding terminals 324b. The hot terminals 324a and the grounding terminals 324b are extracted to the respective castellations 326a and 326b. The surface at the −Y′-axis side of the castellation 326a has the width KB2 in the X-axis direction similarly to the castellation 226a illustrated in FIG. 15B while the surface at the −Y′-axis side of the castellation 326b has the width KC in the X-axis direction similarly to the castellation 226b illustrated in FIG. 15B. The castellation 326a has the width KA1 in the X-axis direction of the first top 228a while the castellation 226b has the width KA2 in the X-axis direction at the second top 228b. The base plate 320 is formed to have the width KA1 equal to the width KA2. In the base plate 320 is formed, similarly to the base plate 220a, the surface at the −Y′-axis side of the castellation 326a has the width KB2 in the X-axis direction that is about 10 to 30% wider than the width KC. This makes the width KA1 equal to the width KA2.

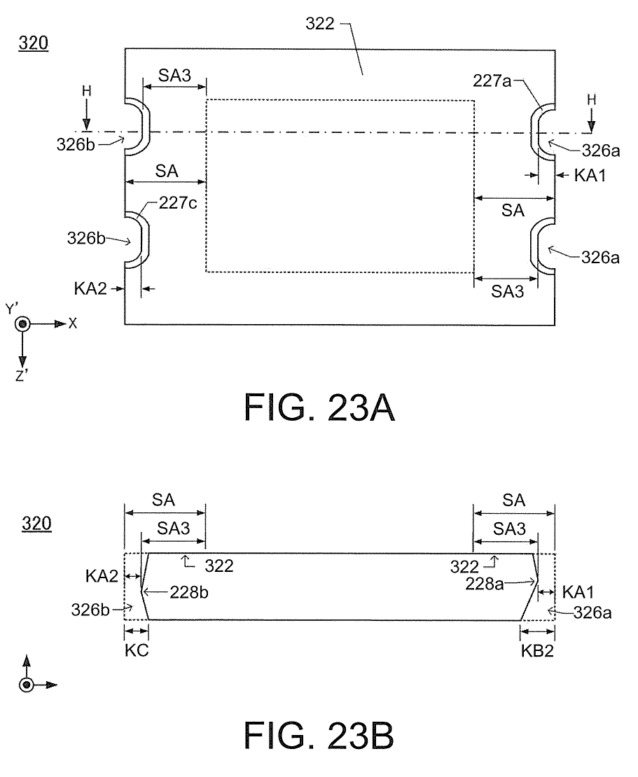

FIG. 23A is a plan view of the surface at the +Y′-axis side of the base plate 320. As illustrated in FIG. 22A, in the base plate 320, the bonding surface 322, the first inclined surface 227a of the castellation 326a, the third inclined surface 227c of the castellation 326b form a bonded area by forming the sealing material 142. This bonded area is to be bonded to the quartz-crystal vibrating piece 330. The base plate 320 has the width SA in the X-axis direction at the +X-axis side and the −X-axis side of the bonding surface 322. The width of the bonded area at the −X-axis side of the castellation 326a and the width of the bonded area at the −X-axis side of the castellation 326b are width SA3. The width SA3 is a size of the width SA minus the width KA1 or the width KA2.

FIG. 23B is a cross-sectional view of the base plate 320. The cross-sectional view of FIG. 23B illustrates a cross section taken along the line H-H of FIG. 23A. The bonded area of the base plate 320 has the width SA at the +X-axis side and the −X-axis side of the base plate 320, and additionally has the width SA3 in the portion where the castellation 326a or 326b is formed. That is, the bonded area has a uniform width in the X-axis direction at the +X-axis side and the −X-axis side of the base plate 320. This provides uniform bonding strength of the sealing material 142 at the +X-axis side and the −X-axis side of the bonded area. This prevents breaking the seal of the quartz crystal device 300.

### Method for Fabricating the Quartz Crystal Device 300

A method for fabricating the quartz crystal device 300 basically follows the flowchart illustrated in FIG. 5. Hereinafter, a description will be given especially of differences from the first Embodiment or the second Embodiment.

In step S201 of FIG. 5, the base wafer (not shown), which includes a plurality of base plates 320, is prepared. On the base wafer in step S201, electrodes are not formed but only an outline of each base plate 320 is formed by etching.

Between step S402 and step S403, that is, in step S402, the base wafer and the quartz-crystal wafer (not shown), which includes a plurality of quartz-crystal vibrating pieces 330, are bonded together. Subsequently, electrodes are formed on the surface at the −Y′-axis side of the base wafer by a method such as sputtering or vacuum evaporation. This forms the hot terminals 324a and the grounding terminals 324b on the base wafer. Electrodes are also formed at the castellations 326a and 326b. Accordingly, as illustrated in FIG. 22A, the hot terminal 324a electrically connects to the extraction electrode 332 of the quartz-crystal vibrating piece 330.

Representative embodiments are described in detail above; however, as will be evident to those skilled in the relevant art, this disclosure may be changed or modified in various ways within its technical scope.

The method for fabricating the quartz crystal device according to a second aspect, in the first aspect, is configured as follows. The exposing exposes the photoresist such that a distance from the center in the X-axis direction of the base plate to the through hole at the +X-axis side has a shorter size on the first surface than a size on the second surface.

The method for fabricating the quartz crystal device according to a third aspect, in the first aspect, is configured as follows. The exposing exposes the photoresist such that a distance from the center of the base plate to the through hole at the +X-axis side becomes equal to a distance from the center of the base plate to the through hole at the −X-axis side on the first surface, and a distance from the center of the base plate to the through hole at the +X-axis side becomes shorter than a distance from the center of the base plate to the through hole at the −X-axis side on the second surface.

The method for fabricating the quartz crystal device according to a fourth aspect, in the first aspect, is configured as follows. The exposing exposes the photoresist such that a distance from the center of the base plate to the through hole at the +X-axis side becomes shorter than a distance from the center of the base plate to the through hole at the −X-axis side on the first surface, and a distance from the center of the base plate to the through hole at the +X-axis side becomes shorter than a distance from the center of the base plate to the through hole at the −X-axis side on the second surface.

The method for fabricating the quartz crystal device according to a fifth aspect, in the first aspect to the fourth aspect, is configured as follows. The quartz-crystal vibrating piece is an AT-cut crystal wafer in a rectangular shape. The method includes bonding a quartz-crystal vibrating piece wafer and the base wafer. The quartz-crystal vibrating piece wafer has at least a pair of through holes in the X-axis direction of the AT-cut crystal wafer. The method for fabricating the quartz crystal device includes forming a corrosion-resistant film on a first surface of the quartz-crystal vibrating piece wafer and a second surface at an opposite side of the first surface, exposing a photoresist on the first surface and the second surface in a position corresponding to the through hole after forming the photoresist on the corrosion-resistant film, etching the corrosion-resistant film corresponding to the through hole on the first surface and the second surface, and performing wet-etching on the first surface and the second surface to form the pair of through holes after the etching corrosion-resistant film. The through hole formed by the wet-etching connects the first surface to the second surface. The through hole has a cross section at a +X-axis side and a cross section at a −X-axis side. The cross section at the +X-axis side includes a first inclined surface, a second inclined surface, and a first top. The first inclined surface is formed toward a center side of the cross section from the first surface. The second inclined surface is formed toward the center side of the cross section from the second surface. The first top is formed at an intersection of the first inclined surface and the second inclined surface. The cross section at the −X-axis side includes a third inclined surface, a fourth inclined surface, and a second top. The third inclined surface is formed toward the center side of the cross section from the first surface. The fourth inclined surface is formed toward the center side of the cross section from the second surface. The second top connects the third inclined surface to the fourth inclined surface. The method further includes the exposing the first surface and the second surface in a position corresponding to the through hole such that a distance from a center of the AT-cut crystal wafer to the first top becomes equal to a distance from the center of the AT-cut crystal wafer to the second top.

The method for fabricating the quartz crystal device according to a sixth aspect, in the fifth aspect, further includes dicing the quartz-crystal vibrating piece wafer and the base wafer bonded together along a middle of the first top and the second top.

A quartz crystal device according to a seventh aspect includes an AT-cut quartz-crystal vibrating piece and an AT-cut quartz-crystal base plate in a rectangular shape. The AT-cut quartz-crystal vibrating piece includes an excitation electrode and an extraction electrode. The extraction electrode is extracted from the excitation electrode. The quartz-crystal base plate supports the quartz-crystal vibrating piece. The base plate has a first surface and a second surface at an opposite side of the first surface. The base plate has a pair of short sides disposed in ±X-axis directions. The short sides each have a castellation depressed toward a center side. The castellation has a cross section at a +X-axis side and a cross section at a −X-axis side. The cross section at the +X-axis side includes a first inclined surface, a second inclined surface, and a first top. The first inclined surface is formed toward a center side of the cross section from the first surface. The second inclined surface is formed toward the center side of the cross section from the second surface. The first top is formed at an intersection of the first inclined surface and the second inclined surface. The cross section at the −X-axis side includes a third inclined surface, a fourth inclined surface, and a second top. The third inclined surface is formed toward the center side of the cross section from the first surface. The fourth inclined surface is formed toward the center side of the cross section from the second surface. The second top connects the third inclined surface to the fourth inclined surface. A distance from a center of the base plate to the first top is equal to a distance from the center in the X-axis direction of the base plate to the second top.

The quartz crystal device according to an eighth aspect, in the seventh aspect, is configured as follows. The first surface of the base plate has a bottom surface and a depressed portion. The bottom surface is depressed from the first surface. The depressed portion has sidewalls that extend from the bottom surface. A distance from the sidewall at the +X-axis side of the depressed portion to the first top is equal to a distance from the sidewall at the −X-axis side of the depressed portion to the second top.

The quartz crystal device according to a ninth aspect, in the seventh aspect and the eighth aspect, is configured as follows. The first surface of the base plate has a connecting electrode. The connecting electrode connects to the extraction electrode of the quartz-crystal vibrating piece. The second surface of the base plate has a mounting terminal. The mounting terminal mounts the quartz crystal device. The castellation of the base plate has a side surface electrode. The side surface electrode connects the connecting electrode to the mounting terminal. A sealing material is formed on the first inclined surface and the third inclined surface.

The quartz crystal device according to a tenth aspect, in the seventh aspect to the ninth aspect, is configured as follows. The AT-cut crystal wafer includes a framing body in a rectangular shape and a castellation. The framing body includes a first surface and a second surface at an opposite side of the first surface. The framing body has a pair of short sides disposed in ±X-axis directions. The castellation is depressed toward a center side at the short sides. The castellation of the AT-cut crystal wafer has a cross section at a +X-axis side and a cross section at a −X-axis side. The cross section at the +X-axis side includes a first inclined surface, a second inclined surface, and a first top. The first inclined surface is formed toward a center side of the cross section from the first surface. The second inclined surface is formed toward the center side of the cross section from the second surface. The first top is formed at an intersection of the first inclined surface and the second inclined surface. The cross section at the −X-axis side includes a third inclined surface, a fourth inclined surface, and a second top. The third inclined surface is formed toward the center side of the cross section from the first surface. The fourth inclined surface is formed toward the center side of the cross section from the second surface. The second top connects the third inclined surface to the fourth inclined surface. A distance from a center in the X-axis direction of the AT-cut crystal wafer to the first top is equal to a distance from the center in the X-axis direction of the base plate to the second top.

The quartz crystal device according to an eleventh aspect, in the seventh aspect to the ninth aspect, is configured as follows. The first surface of the base plate has a circular bonded area. The bonded area is bonded to a lid plate via a sealing material. The lid plate seals the quartz-crystal vibrating piece. The bonded area at the +X-axis side of the base plate without a contact with the castellation in the X-axis direction and the bonded area at the −X-axis side of the base plate have a same width in the X-axis direction. The bonded area at the +X-axis side of the base plate in contact with the castellation in the X-axis direction and the bonded area at the −X-axis side of the base plate have a same width in the X-axis direction.

The quartz crystal device according to a twelfth aspect, in the tenth aspect, is configured as follows. The first surface of the base plate has a circular bonded area. The bonded area is to be bonded to the framing body via a sealing material. The base plate has an area without a contact with the castellation in the X-axis direction. The bonded area at the +X-axis side of the base plate and the bonded area at the −X-axis side of the base plate have a same width in the X-axis direction in the area without a contact with the castellation. The base plate has an area in contact with the castellation in the X-axis direction. The bonded area at the +X-axis side of the base plate and the bonded area at the −X-axis side of the base plate have a same width in the X-axis direction in the area in contact with the castellation.

With the quartz crystal device and the method for fabricating the quartz crystal device according to the embodiment, the castellation can be formed at a uniform distance from the center of the base plate even in the case where the base wafer formed of the quartz-crystal material is used.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A method for fabricating a quartz crystal device using an AT-cut base wafer, the AT-cut base wafer including a plurality of base plates in rectangular shapes, the base plate having at least a pair of through holes in an X-axis direction, the quartz crystal device including a quartz-crystal vibrating piece and the base plate, the method comprising:
forming a corrosion-resistant film on a first surface of the base wafer and a second surface at an opposite side of the first surface;
exposing a photoresist on the first surface and the second surface in a position corresponding to the through hole after forming the photoresist on the corrosion-resistant film;
etching the corrosion-resistant film corresponding to the through hole of the first surface and the second surface; and
performing wet-etching on the first surface and the second surface to form the pair of through holes after the etching corrosion-resistant film, wherein
the through hole formed by the wet-etching connects the first surface to the second surface, the through hole having a cross section at a +X-axis side and a cross section at a −X-axis side, the cross section at the +X-axis side including a first inclined surface, a second inclined surface, and a first top, the first inclined surface being formed toward a center side of the cross section from the first surface, the second inclined surface being formed toward the center side of the cross section from the second surface, the first top being formed at an intersection of the first inclined surface and the second inclined surface, the cross section at the −X-axis side including a third inclined surface, a fourth inclined surface, and a second top, the third inclined surface being formed toward the center side of the cross section from the first surface, the fourth inclined surface being formed toward the center side of the cross section from the second surface, the second top connecting the third inclined surface to the fourth inclined surface, and
the exposing exposes the first surface and the second surface in a position corresponding to the through hole such that a distance from a center in the X-axis direction of the base plate to the first top becomes equal to a distance from the center in the X-axis direction of the base plate to the second top.

2. The method for fabricating the quartz crystal device according to claim 1, wherein
the exposing exposes the photoresist such that a distance from the center of the base plate to the through hole at the +X-axis side has a shorter size on the first surface than a size on the second surface.

3. The method for fabricating the quartz crystal device according to claim 1, wherein
the exposing exposes the photoresist such that a distance from the center of the base plate to the through hole at the +X-axis side becomes equal to a distance from the center of the base plate to the through hole at the −X-axis side on the first surface, and a distance from the center of the base plate to the through hole at the +X-axis side becomes shorter than a distance from the center of the base plate to the through hole at the −X-axis side on the second surface.

4. The method for fabricating the quartz crystal device according to claim 1, wherein
the exposing exposes the photoresist such that a distance from the center of the base plate to the through hole at the +X-axis side becomes shorter than a distance from the center of the base plate to the through hole at the −X-axis side on the first surface, and a distance from the center of the base plate to the through hole at the +X-axis side becomes shorter than a distance from the center of the base plate to the through hole at the −X-axis side on the second surface.

5. The method for fabricating the quartz crystal device according to claim 1, wherein
the quartz-crystal vibrating piece is an AT-cut crystal wafer in a rectangular shape, and
the method comprising:
bonding a quartz-crystal vibrating piece wafer and the base wafer, the quartz-crystal vibrating piece wafer having at least a pair of through holes in the X-axis direction of the AT-cut crystal wafer;
forming a corrosion-resistant film on a first surface of the quartz-crystal vibrating piece wafer and a second surface at an opposite side of the first surface;
exposing a photoresist on the first surface and the second surface in a position corresponding to the through hole after forming the photoresist on the corrosion-resistant film;
etching the corrosion-resistant film corresponding to the through hole on the first surface and the second surface; and
performing wet-etching on the first surface and the second surface to form the pair of through holes after the etching corrosion-resistant film, wherein
the through hole formed by the wet-etching connects the first surface to the second surface, the through hole having a cross section at a +X-axis side and a cross section at a −X-axis side, the cross section at the +X-axis side including a first inclined surface, a second inclined surface, and a first top, the first inclined surface being formed toward a center side of the cross section from the first surface, the second inclined surface being formed toward the center side of the cross section from the second surface, the first top being formed at an intersection of the first inclined surface and the second inclined surface, the cross section at the −X-axis side including a third inclined surface, a fourth inclined surface, and a second top, the third inclined surface being formed toward the center side of the cross section from the first surface, the fourth inclined surface being formed toward the center side of the cross section from the second surface, the second top connecting the third inclined surface to the fourth inclined surface, and
the exposing the first surface and the second surface in a position corresponding to the through hole such that a distance from a center of the AT-cut crystal wafer to the first top becomes equal to a distance from the center of the AT-cut crystal wafer to the second top.

6. The method for fabricating the quartz crystal device according to claim 5, further comprising:
dicing the quartz-crystal vibrating piece wafer and the base wafer bonded together along a middle of the first top and the second top.

7. A quartz crystal device comprising:
an AT-cut quartz-crystal vibrating piece including an excitation electrode and an extraction electrode, the extraction electrode being extracted from the excitation electrode; and
an AT-cut quartz-crystal base plate in a rectangular shape, the quartz-crystal base plate supporting the quartz-crystal vibrating piece, wherein
the base plate has a first surface and a second surface at an opposite side of the first surface, the base plate having a pair of short sides disposed in ±X-axis directions, the short sides each having a castellation depressed toward a center side,
the castellation has a cross section at a +X-axis side and a cross section at a −X-axis side, the cross section at the +X-axis side including a first inclined surface, a second inclined surface, and a first top, the first inclined surface being formed toward a center side of the cross section from the first surface, the second inclined surface being formed toward the center side of the cross section from the second surface, the first top being formed at an intersection of the first inclined surface and the second inclined surface, the cross section at the −X-axis side including a third inclined surface, a fourth inclined surface, and a second top, the third inclined surface being formed toward the center side of the cross section from the first surface, the fourth inclined surface being formed toward the center side of the cross section from the second surface, the second top connecting the third inclined surface to the fourth inclined surface, and
a distance from a center of the base plate to the first top is equal to a distance from the center of the base plate to the second top.

8. The quartz crystal device according to claim 7, wherein
the first surface of the base plate has a bottom surface and a depressed portion, the bottom surface being depressed from the first surface, the depressed portion having sidewalls that extend from the bottom surface, and
a distance from the sidewall at the +X-axis side of the depressed portion to the first top is equal to a distance from the sidewall at the −X-axis side of the depressed portion to the second top.

9. The quartz crystal device according to claim 7, wherein
the first surface of the base plate has a connecting electrode, the connecting electrode connecting to the extraction electrode of the quartz-crystal vibrating piece,
the second surface of the base plate has a mounting terminal, the mounting terminal mounting the quartz crystal device,
the castellation of the base plate has a side surface electrode, the side surface electrode connecting the connecting electrode to the mounting terminal, and
a sealing material is formed on the first inclined surface and the third inclined surface.

10. The quartz crystal device according to claim 7, wherein
the AT-cut crystal wafer includes a framing body in a rectangular shape and a castellation, the framing body including a first surface and a second surface at an opposite side of the first surface, the framing body having a pair of short sides disposed in ±X-axis directions, the castellation being depressed toward a center side at the short sides,
the castellation of the AT-cut crystal wafer has a cross section at a +X-axis side and a cross section at a −X-axis side, the cross section at the +X-axis side including a first inclined surface, a second inclined surface, and a first top, the first inclined surface being formed toward a center side of the cross section from the first surface, the second inclined surface being formed toward the center side of the cross section from the second surface, the first top being formed at an intersection of the first inclined surface and the second inclined surface, the cross section at the −X-axis side including a third inclined surface, a fourth inclined surface, and a second top, the third inclined surface being formed toward the center side of the cross section from the first surface, the fourth inclined surface being formed toward the center side of the cross section from the second surface, the second top connecting the third inclined surface to the fourth inclined surface, and
a distance from a center in the X-axis direction of the AT-cut crystal wafer to the first top is equal to a distance from the center in the X-axis direction of the base plate to the second top.

11. The quartz crystal device according to claim 7, wherein
the first surface of the base plate has a circular bonded area, the bonded area being bonded to a lid plate via a sealing material, the lid plate sealing the quartz-crystal vibrating piece,
the bonded area at the +X-axis side of the base plate without a contact with the castellation in the X-axis direction and the bonded area at the −X-axis side of the base plate have a same width in the X-axis direction, and
the bonded area at the +X-axis side of the base plate in contact with the castellation in the X-axis direction and the bonded area at the −X-axis side of the base plate have a same width in the X-axis direction.

12. The quartz crystal device according to claim 10, wherein
the first surface of the base plate has a circular bonded area, the bonded area being to be bonded to the framing body via a sealing material,
the base plate has an area without a contact with the castellation in the X-axis direction, the bonded area at the +X-axis side of the base plate and the bonded area at the −X-axis side of the base plate having a same width in the X-axis direction in the area without a contact with the castellation, and
the base plate has an area in contact with the castellation in the X-axis direction, the bonded area at the +X-axis side of the base plate and the bonded area at the −X-axis side of the base plate having a same width in the X-axis direction in the area in contact with the castellation.
